(19) United States
(12) Patent Application Publication
(10) Pub. No.: US 2026/0045216 A1
(43) Pub. Date: Feb. 12, 2026

(54) DISPLAY DEVICE

(71) Applicant: Samsung Display Co., Ltd., Yongin-si (KR)

(72) Inventors: Won Jun LEE, Yongin-si (KR); Geum Ju MOON, Yongin-si (KR); Sung Min SON, Yongin-si (KR); Min Ji KIM, Yongin-si (KR)

(21) Appl. No.: 19/195,446

(22) Filed: Apr. 30, 2025

(30) Foreign Application Priority Data
Aug. 12, 2024 (KR) 10-2024-0107275

(51) Int. Cl. G09G 3/3233; H10K 59/131

(52) U.S. Cl. CPC G09G 3/3233; H10K 59/131; G09G 2300/0452; G09G 2300/0819; G09G 2300/0842; G09G 2300/0861; G09G 2310/06; G09G 2310/08; G09G 2320/0233; G09G 2320/0247; G09G 2320/045; G09G 2330/021

(57) ABSTRACT

According to an aspect of the present disclosure, there is provided a display device including a first transistor connected between a driving voltage line and a second node, a sixth transistor connected between the second node and a common voltage line, a light-emitting element connected between the sixth transistor and the common voltage line, and a fourth transistor connected between the second node and an initialization voltage line.

### CROSS-REFERENCE TO RELATED APPLICATION

The present application claims priority to, and the benefit of, Korean Patent Application No. 10-2024-0107275, filed on Aug. 12, 2024, in the Korean Intellectual Property Office, the entire disclosure of which is incorporated herein by reference.

### BACKGROUND

### 1. Field

The present disclosure relates to a display device whose image quality and power consumption can be improved.

### 2. Description of the Related Art

An organic light-emitting display apparatus includes a display element whose luminance is changed by an electric current, for example, an organic light-emitting diode.

### SUMMARY

Aspects of the present disclosure provide a display device whose image quality and power consumption can be improved.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a first transistor connected between a driving voltage line and a second node, a sixth transistor connected between the second node and a common voltage line, a light-emitting element connected between the sixth transistor and the common voltage line, and a fourth transistor connected between the second node and an initialization voltage line.

An initialization voltage of the initialization voltage line may be less than a driving voltage of the driving voltage line.

The display device may further include a second transistor connected between a data line and a first node, a third transistor connected between a third node and the second node, a fifth transistor connected between the driving voltage line and the first node, and a seventh transistor connected between a bias voltage line and the first node, wherein the first transistor is connected between the first node and the second node, and wherein a gate electrode of the first transistor is connected to the third node.

The display device may further include a write gate line connected to a gate electrode of the second transistor, a compensation gate line connected to a gate electrode of the third transistor, an initialization gate line connected to a gate electrode of the fourth transistor, a first emission line connected to a gate electrode of the fifth transistor, a second emission line connected to a gate electrode of the sixth transistor, a bias gate line connected to a gate electrode of the seventh transistor, and a capacitor connected between the driving voltage line and the third node.

The write gate line may be configured to transmit a write gate signal, the compensation gate line is configured to transmit a compensation gate signal, the initialization gate line is configured to transmit an initialization gate signal, the first emission line is configured to transmit a first emission signal, the second emission line is configured to transmit a second emission signal, the bias gate line is configured to transmit a bias gate signal, the driving voltage line is configured to transmit a driving voltage, the common voltage line is configured to transmit a common voltage, the initialization voltage line is configured to transmit an initialization voltage, and the bias voltage line is configured to transmit a bias voltage.

In a first period, the second emission signal and the initialization gate signal may have an active level, and the first emission signal, the compensation gate signal, the write gate signal, and the bias gate signal may have a non-active level.

In a second period after the first period, the compensation gate signal and the bias gate signal may have an active level, and the first emission signal, the second emission signal, the initialization gate signal, and the write gate signal may have a non-active level.

In a third period after the second period, the initialization gate signal and the compensation gate signal may have an active level, and the first emission signal, the second emission signal, the write gate signal, and the bias gate signal may have a non-active level.

In a fourth period after the third period, the compensation gate signal and the write gate signal may have an active level, the first emission signal, the second emission signal, the initialization gate signal, and the bias gate signal may have a non-active level, and a data voltage is provided to the data line.

In a fifth period after the fourth period, the compensation gate signal may have an active level, and the first emission signal, the second emission signal, the initialization gate signal, the write gate signal, and the bias gate signal may have a non-active level.

In a sixth period after the fifth period, the bias gate signal may have an active level, and the first emission signal, the second emission signal, the initialization gate signal, the compensation gate signal, and the write gate signal may have a non-active level.

In a seventh period after the sixth period, the initialization gate signal may have an active level, and the first emission signal, the second emission signal, the compensation gate signal, the write gate signal, and the bias gate signal may have a non-active level.

In an eighth period after the seventh period, the first emission signal and the second emission signal may have an active level, and the initialization gate signal, the compensation gate signal, the write gate signal, and the bias gate signal may have a non-active level.

The fourth transistor may include a transistor that is of a different type from the first transistor, the second transistor, the fifth transistor, the sixth transistor, and the seventh transistor.

The fourth transistor may include an n-type transistor, and the first transistor, the second transistor, the fifth transistor, the sixth transistor, and the seventh transistor may include p-type transistors.

The third transistor may include a transistor of a same type as the fourth transistor.

The third transistor and the fourth transistor may include n-type transistors.

The driving voltage line may include a lower driving voltage line, and an upper driving voltage line above the lower driving voltage line, and connected to the lower driving voltage line through a contact hole of an insulating layer.

The lower driving voltage line may include an extension electrode.

The extension electrode may overlap the first emission line, the second emission line, and the bias voltage line.

According to an aspect of the present disclosure, there is provided an electronic device comprising a display device including a first transistor connected between a driving voltage line and a second node, a sixth transistor connected between the second node and a common voltage line, a light-emitting element connected between the sixth transistor and the common voltage line, and a fourth transistor connected between the second node and an initialization voltage line.

### BRIEF DESCRIPTION OF THE DRAWINGS

These and/or other aspects will become apparent and more readily appreciated from the following description of embodiments, taken in conjunction with the accompanying drawings in which:

FIG. 1 is a perspective view of a display device according to one or more embodiments;

FIG. 2 is a cross-sectional view of the display device according to one or more embodiments;

FIG. 3 is a plan view of a display of the display device according to one or more embodiments;

FIG. 4 is a block diagram of a display panel and a display driver according to one or more embodiments;

FIG. 5 is a circuit diagram of a pixel of the display device according to one or more embodiments;

FIG. 6 is a timing diagram of a first emission signal, a second emission signal, an initialization gate signal, a compensation gate signal, a write gate signal, and a bias gate signal of FIG. 5;

FIG. 7 is a diagram for explaining the operation of the pixel of FIG. 5 in a first period of FIG. 6;

FIG. 8 is a diagram for explaining the operation of the pixel of FIG. 5 in a second period of FIG. 6;

FIG. 9 is a diagram for explaining the operation of the pixel of FIG. 5 in a third period of FIG. 6;

FIG. 10 is a diagram for explaining the operation of the pixel of FIG. 5 in a fourth period of FIG. 6;

FIG. 11 is a diagram for explaining the operation of the pixel of FIG. 5 in a fifth period of FIG. 6;

FIG. 12 is a diagram for explaining the operation of the pixel of FIG. 5 in a sixth period of FIG. 6;

FIG. 13 is a diagram for explaining the operation of the pixel of FIG. 5 in a seventh period of FIG. 6;

FIG. 14 is a diagram for explaining the operation of the pixel of FIG. 5 in an eighth period of FIG. 6;

FIG. 15 shows simulated waveforms of the first emission signal, the second emission signal, the bias gate signal, the compensation gate signal, the initialization gate signal, the write gate signal, a voltage of a source electrode of a first transistor, a voltage of a gate electrode of the first transistor, a voltage of a drain electrode of the first transistor, a voltage of an anode of a light-emitting element, and a current of the light-emitting element;

FIG. 16 shows simulated waveforms for explaining an aspect of the display device according to one or more embodiments;

FIG. 17 is a plan view of a pixel array of the display device according to one or more embodiments;

FIG. 18 is a plan view of only a first pattern layer of FIG. 17;

FIG. 19 is a plan view of only a second pattern layer of FIG. 17;

FIG. 20 is a plan view of only a third pattern layer of FIG. 17;

FIG. 21 is a plan view of only a fourth pattern layer of FIG. 17;

FIG. 22 is a plan view of only a fifth pattern layer of FIG. 17;

FIG. 23 is a plan view of only a sixth pattern layer of FIG. 17;

FIG. 24 is a plan view of only a seventh pattern layer of FIG. 17;

FIG. 25 is a plan view of only an eighth pattern layer of FIG. 17;

FIG. 26 is a plan view of only the second pattern layer and the third pattern layer of FIG. 17;

FIG. 27 is a plan view of only the fifth pattern layer and the sixth pattern layer of FIG. 17;

FIG. 28 is a plan view of a seventh pattern layer of a display device according to one or more embodiments; and

FIG. 29 is a plan view of the sixth pattern layer of FIG. 23 and the seventh pattern layer of FIG. 28.

FIG. 30 is a block diagram of an electronic device according to one embodiment.

FIGS. 31, 32 and 33 are schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below”and “under”can encompass both an orientation of above and below.

The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),”“second-category (or second-set),”etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially”has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

According to a display device of one or more embodiments, flicker can be reduced or minimized even when the display device is driven at a low frequency. In addition, according to the display device of one or more embodiments, leakage current and voltage drop can be reduced. In addition, according to the display device of one or more embodiments, even when an image changes rapidly from a white gray level to a black gray level, an image corresponding to the black gray level can be accurately expressed. In addition, according to the display device of one or more embodiments, a swing width of a data voltage can be reduced. Therefore, according to the display device of one or more embodiments, the image quality and power consumption of the display device can be improved.

However, the aspects of the present disclosure are not restricted to the one set forth herein. The above and other aspects of the present disclosure will become more apparent to one of daily skill in the art to which the present disclosure pertains by referencing the claims.

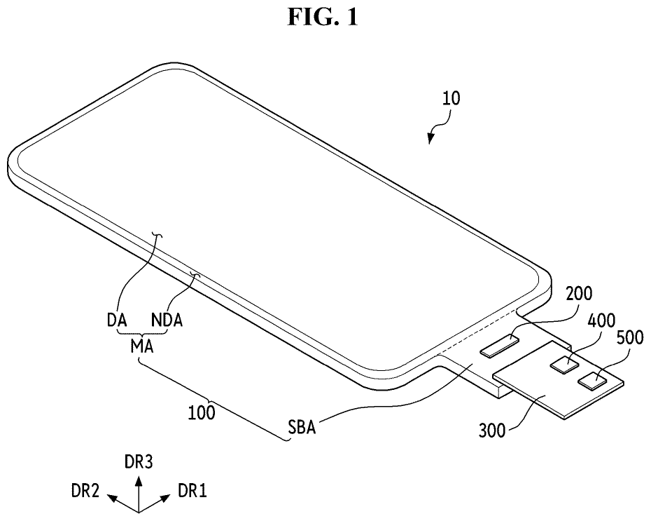

FIG. 1 is a perspective view of a display device 10 according to one or more embodiments.

Referring to FIG. 1, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display of a television, a notebook computer, a monitor, a billboard, or an Internet of things (IoT) device. For another example, the display device 10 may be applied to wearable devices such as smart watches, watch phones, glasses-type displays, and head mounted displays.

The display device 10 may have a planar shape similar to a quadrangle. For example, the display device 10 may have a planar shape similar to a quadrangle having short sides in a first direction DR1 and long sides in a second direction DR2. Each corner where a short side extending in the first direction DR1 meets a long side extending in the second direction DR2 may be rounded to have a corresponding curvature or may be right-angled. The planar shape of the display device 10 is not limited to the quadrangular shape, but may also be similar to other polygonal shapes, a circular shape, or an oval shape.

The display device 10 may include a display panel 100, a display driver 200, a circuit board 300, a touch driver 400, and a power supply 500.

The display panel 100 may include a main area MA and a sub-area SBA.

The main area MA may include a display area DA including pixels that display an image and a non-display area NDA located around the display area DA (e.g., in plan view). The display area DA may emit light from a plurality of emission areas or a plurality of opening areas. For example, the display panel 100 may include pixel circuits including switching elements, a pixel-defining layer defining the emission areas or the opening areas, and self-light-emitting elements.

For example, each of the self-light-emitting elements may include, but is not limited to, at least one of an organic light-emitting diode including an organic light-emitting layer, a quantum dot light-emitting diode including a quantum dot light-emitting layer, an inorganic light-emitting diode including an inorganic semiconductor, and a micro light-emitting diode.

The non-display area NDA may be an area outside the display area DA. The non-display area NDA may be defined as an edge area of the main area MA of the display panel 100. In one or more embodiments, the non-display area NDA may include a gate driver, which supplies gate signals to gate lines and fan-out lines that connect the display driver 200 and the display area DA.

The sub-area SBA may extend from a side of the main area MA. The sub-area SBA may include a flexible material that can be bent, folded, rolled, etc. For example, when the sub-area SBA is bent, it may be overlapped by the main area MA in a thickness direction (e.g., a third direction DR3). The sub-area SBA may include the display driver 200 and a pad (e.g., pad unit) connected to the circuit board 300. Optionally, the sub-area SBA may be omitted, and the display driver 200 and the pad may be located in the non-display area NDA.

The display driver 200 may output signals and voltages for driving the display panel 100. The display driver 200 may supply data voltages to data lines. The display driver 200 may supply a power supply voltage to a power line, and may supply a gate control signal to the gate driver. The display driver 200 may be formed as an integrated circuit and mounted on the display panel 100 by a chip-on-glass (COG) method, a chip-on-plastic (COP) method, or an ultrasonic bonding method. For example, the display driver 200 may be located in the sub-area SBA and may be overlapped by the main area MA in the thickness direction (third direction DR3) by the bending of the sub-area SBA. For another example, the display driver 200 may be mounted on the circuit board 300.

The circuit board 300 may be attached onto the pad of the display panel 100 using an anisotropic conductive film. Lead lines of the circuit board 300 may be electrically connected to the pad of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensor (e.g., touch-sensing unit) of the display panel 100. The touch driver 400 may supply a touch-driving signal to a plurality of touch electrodes of the touch sensor and sense a change in capacitance between the touch electrodes. For example, the touch-driving signal may be a pulse signal having a frequency (e.g., predetermined frequency). The touch driver 400 may determine whether an input has been made based on a change in capacitance between the touch electrodes and calculate coordinates of the input. The touch driver 400 may be formed as an integrated circuit.

The power supply 500 may be located on the circuit board 300 and may supply a power supply voltage to the display driver 200 and the display panel 100 (as used herein, “located on” may mean “above”). The power supply 500 may generate a driving voltage, and supply the driving voltage to a driving voltage line VDL, may generate an initialization voltage and supply the initialization voltage to an initialization voltage line, may generate a bias voltage and supply the bias voltage to a bias voltage line, and may generate a common voltage and supply the common voltage to a common voltage line. Here, the common voltage of the common voltage line may be supplied to a cathode common to light-emitting elements ED of a plurality of pixels PX. The driving voltage may be a high potential voltage for driving the light-emitting elements ED, and the common voltage may be a low potential voltage for driving the light-emitting elements ED.

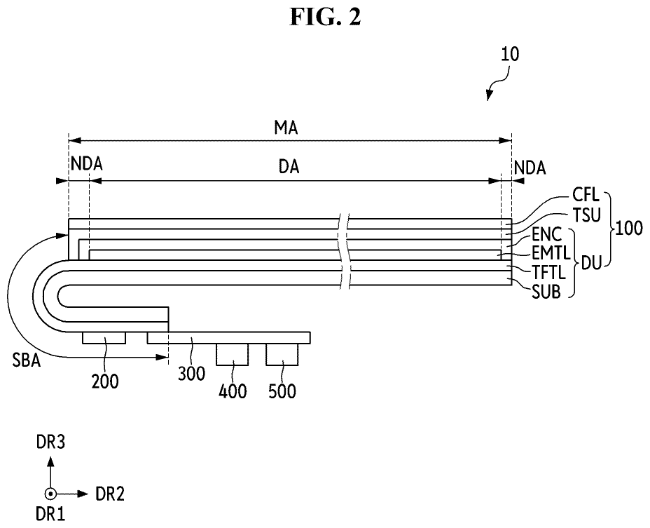

FIG. 2 is a cross-sectional view of the display device 10 according to one or more embodiments.

Referring to FIG. 2, the display panel 100 may include a display DU, a touch sensor TSU, and a color filter layer CFL. The display DU may include a substrate SUB, a thin-film transistor layer TFTL, a light-emitting element layer EMTL, and an encapsulation layer ENC.

The substrate SUB may be a base substrate or a base member. The substrate SUB may be a flexible substrate that can be bent, folded, rolled, etc. For example, the substrate SUB may include polymer resin such as polyimide (PI), but the present disclosure is not limited thereto. For another example, the substrate SUB may include a glass material or a metal material.

The thin-film transistor layer TFTL may be located on the substrate SUB. The thin-film transistor layer TFTL may include a plurality of thin-film transistors constituting pixel circuits of pixels. The thin-film transistor layer TFTL may further include gate lines, data lines, power lines, gate control lines, fan-out lines connecting the display driver 200 and the data lines, and lead lines connecting the display driver 200 and the pad. Each of the thin-film transistors may include a semiconductor region, a source electrode, a drain electrode, and a gate electrode. For example, when the gate driver is formed on a side of the non-display area NDA of the display panel 100, it may include thin-film transistors.

The thin-film transistor layer TFTL may be located in the display area DA, the non-display area NDA, and the sub-area SBA. The thin-film transistors of the pixels, the gate lines, the data lines, and the power lines of the thin-film transistor layer TFTL may be located in the display area DA. The gate control lines and the fan-out lines of the thin-film transistor layer TFTL may be located in the non-display area NDA. The lead lines of the thin-film transistor layer TFTL may be located in the sub-area SBA.

The light-emitting element layer EMTL may be located on the thin-film transistor layer TFTL. The light-emitting element layer EMTL may include a plurality of light-emitting elements ED, each including a first electrode (hereinafter, referred to as an anode), a light-emitting layer, and a second electrode (hereinafter, referred to as a cathode) sequentially stacked to emit light, and a pixel-defining layer defining the pixels. The light-emitting elements ED of the light-emitting element layer EMTL may be located in the display area DA.

For example, the light-emitting layer may be an organic light-emitting layer including an organic material. The light-emitting layer may include a hole-transporting layer, an organic light-emitting layer, and an electron-transporting layer. When the anode receives a voltage (e.g., predetermined voltage) through a thin-film transistor of the thin-film transistor layer TFTL and the cathode receives a cathode voltage, holes and electrons may move to the organic light-emitting layer through the hole-transporting layer and the electron-transporting layer, respectively. Then, the holes and the electrons may be combined with each other in the organic light-emitting layer to emit light.

For another example, each of the light-emitting elements ED may include a quantum dot light-emitting diode including a quantum dot light-emitting layer, an inorganic light-emitting diode including an inorganic semiconductor, or a micro light-emitting diode.

The encapsulation layer ENC may cover upper and side surfaces of the light-emitting element layer EMTL, and may protect the light-emitting element layer EMTL. The encapsulation layer ENC may include at least one inorganic layer and at least one organic layer to encapsulate the light-emitting element layer EMTL.

The touch sensor TSU may be located on the encapsulation layer ENC. The touch sensor TSU may include a plurality of touch electrodes for sensing a user's touch in a capacitive manner and touch lines connecting the touch electrodes and the touch driver 400. For example, the touch sensor TSU may sense a user's touch in a mutual capacitance manner or a self-capacitance manner.

For another example, the touch sensor TSU may be located on a separate substrate located on the display DU. In this case, the substrate supporting the touch sensor TSU may be a base member that encapsulates the display DU.

The touch electrodes of the touch sensor TSU may be located in a touch sensor area overlapping the display area DA. The touch lines of the touch sensor TSU may be located in a touch peripheral area overlapping the non-display area NDA.

The color filter layer CFL may be located on the touch sensor TSU. The color filter layer CFL may include a plurality of color filters corresponding to a plurality of emission areas, respectively. Each of the color filters may selectively transmit light of a corresponding wavelength, and may block or absorb light of other wavelengths. The color filter layer CFL may absorb a part of light coming from the outside of the display device 10, thereby reducing reflected light caused by the external light. Therefore, the color filter layer CFL can reduce or prevent color distortion caused by reflection of external light.

Because the color filter layer CFL is directly located on the touch sensor TSU, the display device 10 may not require a separate substrate for the color filter layer CFL. Therefore, a thickness of the display device 10 can be relatively reduced.

The sub-area SBA of the display panel 100 may extend from a side of the main area MA. The sub-area SBA may include a flexible material that can be bent, folded, rolled, etc. For example, when the sub-area SBA is bent, it may be overlapped by the main area MA in the thickness direction (third direction DR3). The sub-area SBA may include the display driver 200 and the pad electrically connected to the circuit board 300.

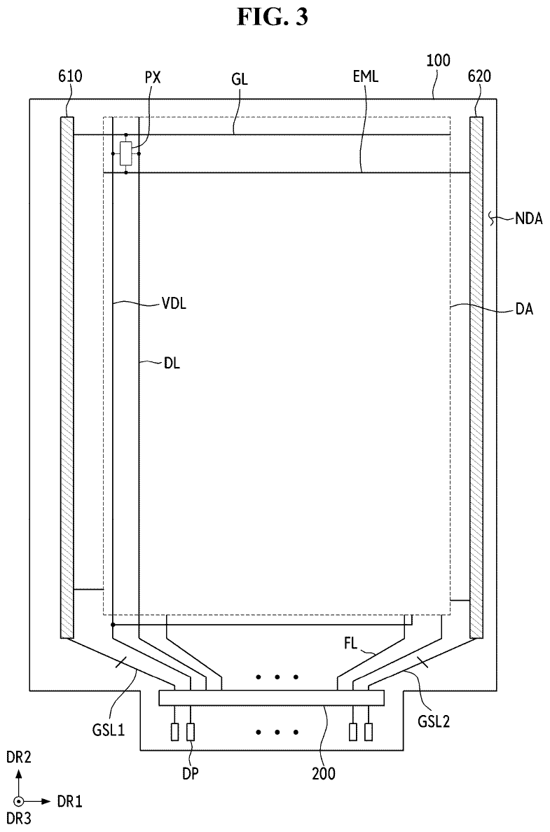

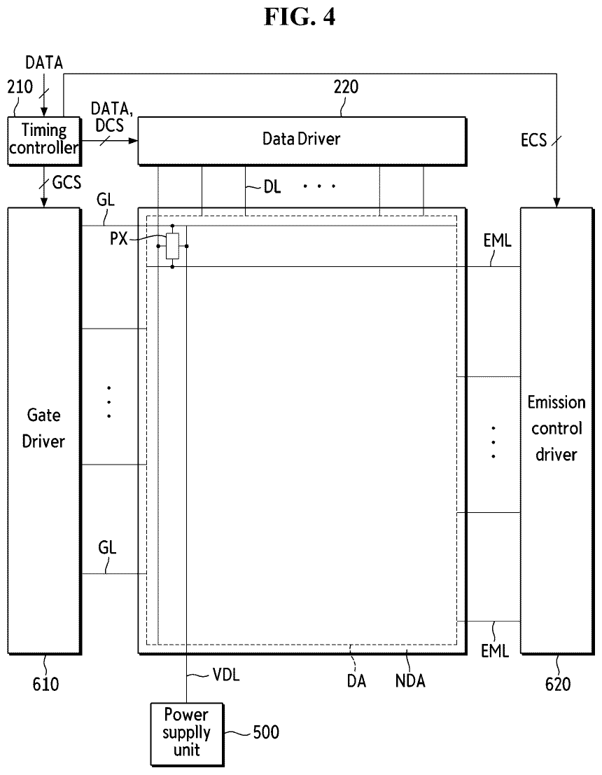

FIG. 3 is a plan view of the display DU of the display device 10 according to one or more embodiments. FIG. 4 is a block diagram of the display panel 100 and the display driver 200 according to one or more embodiments.

Referring to FIGS. 3 and 4, the display panel 100 may include the display area DA and the non-display area NDA.

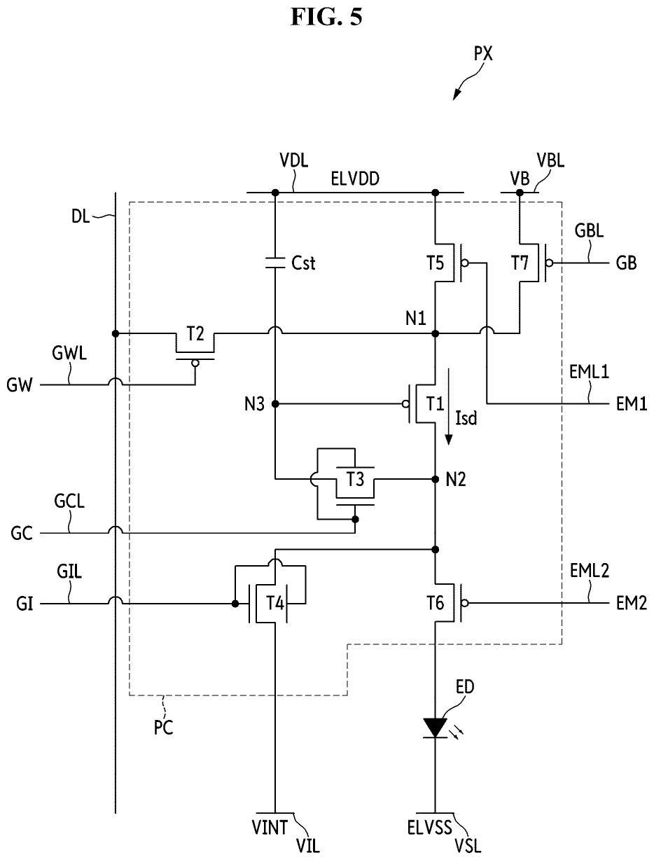

The display area DA may include a plurality of pixels PX, a plurality of driving voltage lines VDL connected to the pixels PX, a plurality of gate lines GL of a plurality of common voltage lines VSL (see FIG. 5), a plurality of emission lines EML, and a plurality of data lines DL.

Each of the pixels PX may be connected to a gate line GL, a data line DL, an emission line EML, a driving voltage line VDL, and a common voltage line VSL. Each of the pixels PX may include at least one transistor, a light-emitting element ED, and/or a capacitor.

The gate lines GL may extend in the first direction DR1, and may be spaced apart from each other in the second direction DR2 crossing the first direction DR1. The gate lines GL may be arranged along the second direction DR2. The gate lines GL may sequentially supply gate signals to the pixels PX.

The emission lines EML may extend in the first direction DR1, and may be spaced apart from each other in the second direction DR2. The emission lines EML may be arranged along the second direction DR2. The emission lines EML may sequentially supply emission signals to the pixels PX.

The data lines DL may extend in the second direction DR2 and may be spaced apart from each other in the first direction DR1. The data lines DL may be arranged along the first direction DR1. The data lines DL may supply data voltages to the pixels PX. A data voltage may determine the luminance of each of the pixels PX.

The driving voltage lines VDL may extend in the second direction DR2 and may be spaced apart from each other in the first direction DR1. The driving voltage lines VDL may be arranged along the first direction DR1. The driving voltage lines VDL may supply driving voltages to the pixels PX. The driving voltages may be high potential voltages for driving the light-emitting elements ED of the pixels PX.

The non-display area NDA may surround the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply data voltages received from the display driver 200 to the data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-area SBA may extend from a side of the non-display area NDA. The sub-area SBA may include the display driver 200 and a pad DP. The pad DP may be closer to an edge of the sub-area SBA than the display driver 200 is. The pad DP may be electrically connected to the circuit board 300 through an anisotropic conductive film.

The display driver 200 may include a timing controller 210 and a data driver 220.

The timing controller 210 may receive digital video data DATA and timing signals from the circuit board 300. The timing controller 210 may control the operation timing of the data driver 220 by generating a data control signal DCS based on the timing signals, may control the operation timing of the gate driver 610 by generating the gate control signal GCS, and may control the operation timing of the emission control driver 620 by generating the emission control signal ECS. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages, and may supply the analog data voltages to the data lines DL through the fan-out lines FL. Gate signals of the gate driver 610 may select pixels PX to which the data voltages are to be supplied, and the selected pixels PX may receive the data voltages through the data lines DL.

The power supply 500 may be located on the circuit board 300 to supply a power supply voltage to the display driver 200 and the display panel 100. The power supply 500 may generate a driving voltage, and may supply the driving voltage to the driving voltage lines VDL, may generate an initialization voltage, and may supply the initialization voltage to initialization voltage lines VIL, may generate a common voltage, and may supply the common voltage to a cathode common to the light-emitting elements ED of the pixels PX.

The gate driver 610 may be located outside one side of the display area DA or on one side of the non-display area NDA, and the emission control driver 620 may be located outside the other side of the display area DA or on the other side of the non-display area NDA. However, the present disclosure is not limited thereto. For another example, the gate driver 610 and the emission control driver 620 may be located on either one side or the other side of the non-display area NDA.

The gate driver 610 may include a plurality of transistors that generate gate signals based on the gate control signal GCS. The emission control driver 620 may include a plurality of transistors that generate emission signals based on the emission control signal ECS. For example, the transistors of the gate driver 610 and the transistors of the emission control driver 620 may be formed on the same layer as the transistors of the pixels PX. The gate driver 610 may supply the gate signals to the gate lines GL, and the emission control driver 620 may supply the emission signals to the emission control lines EML.

FIG. 5 is a circuit diagram of a pixel PX of the display device 10 according to one or more embodiments.

As illustrated in FIG. 5, the pixel PX may be connected to a write gate line GWL, a compensation gate line GCL, an initialization gate line GIL, a bias gate line GBL, a first emission line EML1, a second emission line EML2, a data line DL, a driving voltage line VDL, a common voltage line VSL, an initialization voltage line VIL, and a bias voltage line VBL.

The pixel PX may include a pixel circuit PC and a light-emitting element ED. The pixel circuit PC may include a first transistor T1, a second transistor T2, a third transistor T3, a fourth transistor T4, a fifth transistor T5, a sixth transistor T6, a seventh transistor T7, and a capacitor Cst.

The first transistor T1 may include a gate electrode, a source electrode, and a drain electrode. The first transistor T1 may control a source-drain current (hereinafter, referred to as a driving current) according to a data voltage applied to the gate electrode. The driving current (e.g., Isd) flowing through a channel region of the first transistor T1 may be proportional to the square of a difference between a voltage Vsg between the source electrode and the gate electrode of the first transistor T1 and a threshold voltage Vth (Isd=k×(Vsg−Vth)²), where k is a proportional coefficient determined by the structure and physical characteristics of the first transistor T1, Vsg is a source-gate voltage of the first transistor T1, and Vth is a threshold voltage of the first transistor T1.

The light-emitting element ED may receive the driving current Isd and may emit light. The amount of light emitted from the light-emitting element ED or the luminance of the light-emitting element ED may be proportional to the magnitude of the driving current Isd.

The light-emitting element ED may be an organic light-emitting diode including an anode, a cathode, and an organic light-emitting layer located between these electrodes (e.g., the anode and the cathode). For another example, the light-emitting element ED may be an inorganic light-emitting element ED including an anode, a cathode, and an inorganic semiconductor located between these electrodes (e.g., the anode and the cathode). For another example, the light-emitting element ED may be a quantum dot light-emitting element ED including an anode, a cathode, and a quantum dot light-emitting layer located between these electrodes (e.g., the anode and the cathode). For another example, the light-emitting element ED may be a micro light-emitting diode.

The anode of the light-emitting element ED may be electrically connected to a second node N2. The anode of the light-emitting element ED may be connected to a drain electrode of the sixth transistor T6 through the second node N2. The cathode of the light-emitting element ED may be connected to the common voltage line VSL. The cathode of the light-emitting element ED may receive a common voltage ELVSS (e.g., a low potential voltage) from the common voltage line VSL.

The second transistor T2 may be turned on by a write gate signal GW from the write gate line GWL to electrically connect the data line DL and a first node N1, which is the source electrode of the first transistor T1. The second transistor T2 turned on based on the write gate signal GW may supply a data voltage to the first node N1. The second transistor T2 may have a gate electrode electrically connected to the write gate line GWL, a source electrode electrically connected to the data line DL, and a drain electrode electrically connected to the first node N1.

The third transistor T3 may be turned on by a compensation gate signal GC from the compensation gate line GCL to electrically connect the second node N2, which is the drain electrode of the first transistor T1, and a third node N3, which is the gate electrode of the first transistor T1. The third transistor T3 may be connected between the third node N3 and the second node N2. For example, the third transistor T3 may have a gate electrode electrically connected to the compensation gate line GCL, a source electrode electrically connected to the third node N3, and a drain electrode electrically connected to the second node N2. The third transistor T3 turned on by the compensation gate signal GC of the compensation gate line GCL may electrically connect the second node N2, which is the drain electrode of the first transistor T1, and the third node N3, which is the gate electrode of the first transistor T1. The third transistor T3 may be a double-gate transistor having two gate electrodes (e.g., a gate electrode and a counter gate electrode). The gate electrode and the counter gate electrode may be located on different layers to face each other.

The fourth transistor T4 may be turned on by an initialization gate signal GI from the initialization gate line GIL to electrically connect the second node N2 and the initialization voltage line VIL. The fourth transistor T4 may be connected between the second node N2 and the first initialization voltage line VIL. For example, the fourth transistor T4 may have a gate electrode electrically connected to the initialization gate line GIL, a drain electrode electrically connected to the second node N2, and a source electrode electrically connected to the initialization voltage line VIL. The fourth transistor T4 may be a double-gate transistor. The initialization voltage line VIL may transmit an initialization voltage VINT.

The fifth transistor T5 may be turned on by a first emission control signal EM1 from the first emission line EML1 to electrically connect the driving voltage line VDL and the first node N1, which is the source electrode of the first transistor T1.

The fifth transistor T5 may have a gate electrode electrically connected to the first emission line EML1, a source electrode electrically connected to the driving voltage line VDL, and a drain electrode electrically connected to the first node N1.

The sixth transistor T6 may be turned on by a second emission control signal EM2 from the second emission line EML2 to electrically connect the second node N2, which is the drain electrode of the first transistor T1, and the anode of the light-emitting element ED. The sixth transistor T6 may have a gate electrode electrically connected to the second emission line EML2, the drain electrode electrically connected to the second node N2, and a source electrode electrically connected to the anode of the light-emitting element ED. When the fifth transistor T5, the first transistor T1, and the sixth transistor T6 are all turned on, the driving current Isd may be supplied to the light-emitting element ED.

The seventh transistor T7 may be turned on by a bias gate signal GB from the bias gate line GBL to electrically connect the bias voltage line VBL and the first node N1, which is the source electrode of the first transistor T1. The seventh transistor T7 turned on based on the bias gate signal GB may supply a bias voltage VB to the first node N1. The seventh transistor T7 may improve the hysteresis of the first transistor T1 by supplying the bias voltage VB to the source electrode of the first transistor T1. The seventh transistor T7 may have a gate electrode electrically connected to the bias gate line GBL, a source electrode electrically connected to the bias voltage line VBL, and a drain electrode electrically connected to the first node N1.

Each of the first transistor T1, the second transistor T2, the fifth transistor T5, the sixth transistor T6, and the seventh transistor T7 may include a silicon-based active layer. For example, each of the first transistor T1, the second transistor T2, the fifth transistor T5, the sixth transistor T6, and the seventh transistor T7 may be a p-type transistor including an active layer made of low temperature polycrystalline silicon (LTPS). The active layer made of low temperature polycrystalline silicon may have high electron mobility and excellent turn-on characteristics. Therefore, the display device 10 including transistors with excellent turn-on characteristics can stably and efficiently drive the pixels PX. Each of the first transistor T1, the second transistor T2, the fifth transistor T5, the sixth transistor T6, and the seventh transistor T7 may output a current, which flows into the source electrode, to the drain electrode based on a gate-low voltage applied to the gate electrode.

Each of the third transistor T3 and the fourth transistor T4 may be an n-type transistor including an oxide-based active layer. A transistor including an oxide-based active layer may have a coplanar structure in which a gate electrode is located at the top. The transistor including the oxide-based active layer may output a current, which flows into a drain electrode, to a source electrode based on a gate-high voltage applied to the gate electrode.

The capacitor Cst may be electrically connected between the third node N3, which is the gate electrode of the first transistor T1, and the driving voltage line VDL. For example, a first electrode of the capacitor Cst may be electrically connected to the third node N3, and a second electrode of the capacitor Cst may be electrically connected to the driving voltage line VDL, thereby maintaining a potential difference between the driving voltage line VDL and the gate electrode of the first transistor T1.

The bias voltage VB may be greater than a driving voltage ELVDD, the driving voltage ELVDD may be greater than the common voltage ELVSS, and the common voltage ELVSS may be greater than the initialization voltage VINT.

However, the present disclosure is not limited thereto. For example, the common voltage ELVSS may be equal to or less than the initialization voltage VINT. The bias voltage VB may be a voltage (e.g., a voltage of about 5 V) that is relatively close to a black gray level.

Each pixel PX of FIG. 3 described above may have the circuit configuration illustrated in FIG. 5.

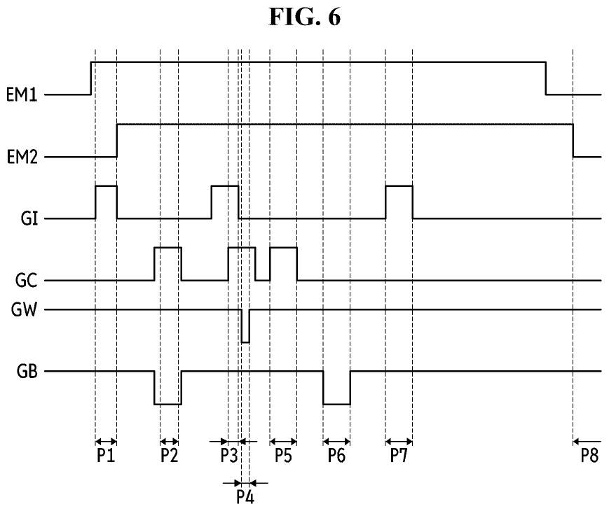

FIG. 6 is a timing diagram of the first emission signal EM1, the second emission signal EM2, the initialization gate signal GI, the compensation gate signal GC, the write gate signal GW, and the bias gate signal GB of FIG. 5.

Referring to FIG. 6, the display device 10 may operate based on a first period P1, a second period P2, a third period P3, a fourth period P4, a fifth period P5, a sixth period P6, a seventh period P7, and an eighth period P8.

The first emission signal EM1, the second emission signal EM2, the initialization gate signal GI, the compensation gate signal GC, the write gate signal GW, and the bias gate signal GB may have an active level or a non-active level in each of the periods P1 through P8. Here, the active level of each of the signals EM1, EM2, GI, GC, GW, and GB described above may refer to a voltage level that can turn on a corresponding transistor to which the signal is transmitted. In other words, a signal at the active level may have a greater value than a threshold voltage of a corresponding transistor. For example, when a corresponding transistor is an n-type transistor, the active level of a signal transmitted to a gate electrode of the corresponding transistor may refer to a high level (e.g., a positive level or a high voltage level).

The non-active level of each of the signals EM1, EM2, GI, GC, GW, and GB may refer to a voltage level that can turn off a corresponding transistor. In other words, a signal at the non-active level may have a smaller value than a threshold voltage of a corresponding transistor. For example, when a corresponding transistor is an n-type transistor, the non-active level of a signal transmitted to a gate electrode of the corresponding transistor may refer to a low level (e.g., a negative level or a low voltage level).

In contrast, when a corresponding transistor is a p-type transistor, the active level of a signal transmitted to a gate electrode of the corresponding transistor may refer to a low level (e.g., a negative level or a low voltage level), and the non-active level of the signal transmitted to the gate electrode of the corresponding transistor may refer to a high level (e.g., a positive level or a high voltage level).

In the first period P1, the second emission signal EM2, and the initialization gate signal GI may each have the active level. In the first period P1, the first emission signal EM1, the compensation gate signal GC, the write gate signal GW, and the bias gate signal GB may each have the non-active level. The first period P1 may be, for example, a period for initializing the voltage of the anode of the light-emitting element ED.

In the second period P2, the compensation gate signal GC and the bias gate signal GB may each have the active level. In the second period P2, the first emission signal EM1, the second emission signal EM2, the initialization gate signal GI, and the write gate signal GW may each have the non-active level. The second period P2 may be, for example, a period for improving the hysteresis of the first transistor T1.

In the third period P3, the initialization gate signal GI and the compensation gate signal GC may each have the active level. In the third period P3, the first emission signal EM1, the second emission signal EM2, the write gate signal GW, and the bias gate signal GB may each have the non-active level. The third period P3 may be, for example, a period for initializing the voltage of the gate electrode of the first transistor T1.

In the fourth period P4, the compensation gate signal GC and the write gate signal GW may each have the active level. In the fourth period P4, the first emission signal EM1, the second emission signal EM2, the initialization gate signal GI, and the bias gate signal GB may each have the non-active level. In addition, in the fourth period P4, a data voltage may be provided to the data line DL. The fourth period P4 may be, for example, a period for supplying the data voltage to the pixel circuit PC and detecting and compensating for the threshold voltage of the first transistor T1.

In the fifth period P5, the compensation gate signal GC may have the active level. In the fifth period P5, the first emission signal EM1, the second emission signal EM2, the initialization gate signal GI, the write gate signal GW, and the bias gate signal GB may each have the non-active level. The fifth period P5 may be, for example, a period for additionally compensating for the threshold voltage of the first transistor T1.

In the sixth period P6, the bias gate signal GB may have the active level. In the sixth period P6, the first emission signal EM1, the second emission signal EM2, the initialization gate signal GI, the compensation gate signal GC, and the write gate signal GW may each have the non-active level. The sixth period P6 may be, for example, a period for additionally improving the hysteresis of the first transistor T1.

In the seventh period P7, the initialization gate signal GI may have the active level. In the seventh period P7, the first emission signal EM1, the second emission signal EM2, the compensation gate signal GC, the write gate signal GW, and the bias gate signal GB may each have the non-active level. The seventh period P7 may be, for example, a period for improving the expression of a black gray level by discharging the voltage of the drain electrode of the first transistor T1.

In the eighth period P8, the first emission signal EM1 and the second emission signal EM2 may each have the active level. In the eighth period P8, the initialization gate signal GI, the compensation gate signal GC, the write gate signal GW, and the bias gate signal GB may each have the non-active level. The eighth period P8 may be, for example, a period for emitting light from the light-emitting element ED.

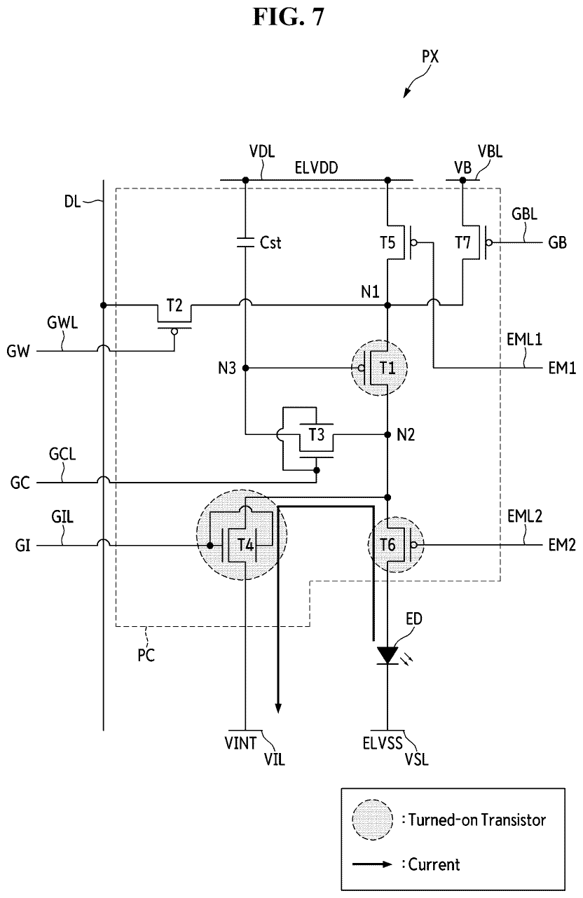

The operation of the display device 10 according to one or more embodiments will be described as follows with reference to FIGS. 7 through 14. In FIGS. 7 through 14, transistors surrounded by dotted circles may be turned-on transistors, and transistors other than the transistors surrounded by the dotted circles may be turned-off transistors.

First, the operation of a pixel PX in the first initialization period P1 will be described as follows with reference to FIGS. 6 and 7.

FIG. 7 is a diagram for explaining the operation of the pixel PX of FIG. 5 in the first period P1 of FIG. 6.

As illustrated in FIG. 6, in the first period P1, the second emission signal EM2 and the initialization gate signal GI may each have an active level. In the first period P1, the first emission signal EM1, the compensation gate signal GC, the write gate signal GW, and the bias gate signal GB may each have a non-active level.

The first transistor T1 may be kept turned on by a data voltage in a previous frame period. For example, the voltage of the gate electrode (e.g., the first node N1) of the first transistor T1 may include the data voltage provided in the previous frame period. Therefore, the first transistor T1 may be turned on by the data voltage of the previous frame period.

The initialization gate signal GI at the active level may be transmitted to the gate electrode of the fourth transistor T4 through the initialization gate line GIL. Accordingly, the fourth transistor T4 may be turned on.

The second emission signal EM2 at the active level may be transmitted to the gate electrode of the sixth transistor T6 through the second emission line EML2. Accordingly, the sixth transistor T6 may be turned on.

The write gate signal GW at the non-active level may be transmitted to the gate electrode of the second transistor T2 through the write gate line GWL. Accordingly, the second transistor T2 may be turned off.

The compensation gate signal GC at the non-active level may be transmitted to the gate electrode of the third transistor T3 through the compensation gate line GCL. Accordingly, the third transistor T3 may be turned off.

The first emission signal EM1 at the non-active level may be transmitted to the gate electrode of the fifth transistor T5 through the first emission line EML1. Accordingly, the fifth transistor T5 may be turned off.

The bias gate signal GB at the non-active level may be transmitted to the gate electrode of the seventh transistor T7 through the bias gate line GBL. Accordingly, the seventh transistor T7 may be turned off.

As the fourth transistor T4 and the sixth transistor T6 are turned on as described above, the initialization voltage VINT from the initialization voltage line VIL may be applied to each of the second node N2 and the anode of the light-emitting element ED through the turned-on fourth transistor T4 and sixth transistor T6. Therefore, in the first period P1, the voltage of the anode of the light-emitting element ED and the voltage of the source electrode of the first transistor T1 connected to the second node N2 may each be initialized to the initialization voltage VINT.

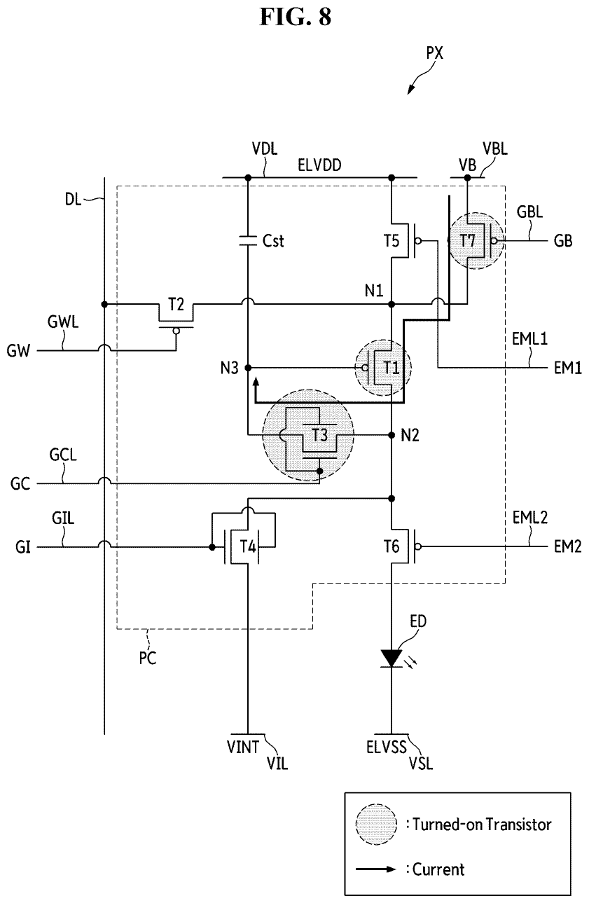

Next, the operation of a pixel PX in the second period P2 will be described as follows with reference to FIGS. 6 and 8.

FIG. 8 is a diagram for explaining the operation of the pixel PX of FIG. 5 in the second period P2 of FIG. 6.

As illustrated in FIG. 6, in the second period P2, the compensation gate signal GC and the bias gate signal GB may each have an active level. In the second period P2, the first emission signal EM1, the second emission signal EM2, the initialization gate signal GI, and the write gate signal GW may each have a non-active level.

The compensation gate signal GC at the active level may be transmitted to the gate electrode of the third transistor T3 through the compensation gate line GCL. Accordingly, the third transistor T3 may be turned on.

The bias gate signal GB at the active level may be transmitted to the gate electrode of the seventh transistor T7 through the bias gate line GBL. Accordingly, the seventh transistor T7 may be turned on.

The write gate signal GW at the non-active level may be transmitted to the gate electrode of the second transistor T2 through the write gate line GWL. Accordingly, the second transistor T2 may be turned off.

The initialization gate signal GI at the non-active level may be transmitted to the gate electrode of the fourth transistor T4 through the initialization gate line GIL. Accordingly, the fourth transistor T4 may be turned off.

The first emission signal EM1 at the non-active level may be transmitted to the gate electrode of the fifth transistor T5 through the first emission line EML1. Accordingly, the fifth transistor T5 may be turned off.

The second emission signal EM2 at the non-active level may be transmitted to the gate electrode of the sixth transistor T6 through the second emission line EML2. Accordingly, the sixth transistor T6 may be turned off.

As the seventh transistor T7 is turned on as described above, the bias voltage VB from the bias voltage line VBL may be applied to the source electrode (e.g., the first node N1) of the first transistor T1 through the turned-on seventh transistor T7. Then, a voltage difference (hereinafter, referred to as a gate-source voltage) between the gate electrode of the first transistor T1 and the source electrode of the first transistor T1 may become greater than the threshold voltage of the first transistor T1. Accordingly, the first transistor T1 may be turned on.

As the third transistor T3 is turned on as described above, the gate electrode (e.g., the third node N3) and the drain electrode (e.g., the second node N2) of the first transistor T1 may be electrically connected to each other. In other words, the first transistor T1 may be connected to the pixel circuit PC in a diode form. Accordingly, a current may be generated to flow in a direction from the bias voltage line VBL toward the drain electrode (e.g., the second node N2) and the source electrode (e.g., the third node N3) of the first transistor T1 through the turned-on first transistor T1. Accordingly, the voltage of the gate electrode (e.g., the first node N1) of the first transistor T1 may increase, and when the gate-source voltage of the first transistor T1 becomes equal to the threshold voltage of the first transistor T1, the first transistor T1 may be turned off.

As the first transistor T1, the third transistor T3, and the seventh transistor T7 are turned on as described above, the bias voltage VB from the bias voltage line VBL may be applied to each of the first node N1, the second node N2, and the third node N3 through the turned-on first transistor T1, third transistor T3, and seventh transistor T7. Therefore, in the second period P2, the hysteresis of the first transistor T1 can be improved. In addition, in the second period P2, the voltage of the source electrode of the first transistor T1 may be initialized to the bias voltage VB.

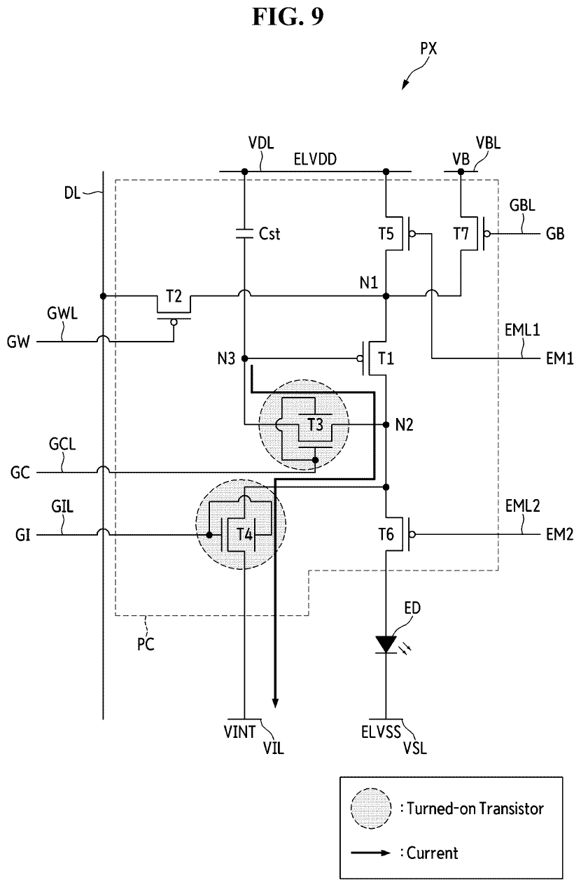

Next, the operation of a pixel PX in the third period P3 will be described as follows with reference to FIGS. 6 and 9.

FIG. 9 is a diagram for explaining the operation of the pixel PX of FIG. 5 in the third period P3 of FIG. 6.

As illustrated in FIG. 6, in the third period P3, the initialization gate signal GI and the compensation gate signal GC may each have an active level. In the third period P3, the first emission signal EM1, the second emission signal EM2, the write gate signal GW, and the bias gate signal GB may each have a non-active level.

The compensation gate signal GC at the active level may be transmitted to the gate electrode of the third transistor T3 through the compensation gate line GCL. Accordingly, the third transistor T3 may be turned on.

The initialization gate signal GI at the active level may be transmitted to the gate electrode of the fourth transistor T4 through the initialization gate line GIL. Accordingly, the fourth transistor T4 may be turned on.

The first emission signal EM1 at the non-active level may be transmitted to the gate electrode of the fifth transistor T5 through the first emission line EML1. Accordingly, the fifth transistor T5 may be turned off.

The second emission signal EM2 at the non-active level may be transmitted to the gate electrode of the sixth transistor T6 through the second emission line EML2. Accordingly, the sixth transistor T6 may be turned off.

The bias gate signal GB at the non-active level may be transmitted to the gate electrode of the seventh transistor T7 through the bias gate line GBL. Accordingly, the seventh transistor T7 may be turned off.

As the third transistor T3 is turned on as described above, the gate electrode (e.g., the third node N3) and the drain electrode (e.g., the second node N2) of the first transistor T1 may be electrically connected to each other. Meanwhile, the first transistor T1 may remain turned off from a previous period (e.g., the second period P2).

As the third transistor T3 and the fourth transistor T4 are turned on as described above, the initialization voltage VINT from the initialization voltage line VIL may be applied to each of the second node N2 and the third node N3 through the turned-on third transistor T3 and fourth transistor T4. Therefore, in the third period P3, the voltage of the gate electrode of the first transistor T1 and the voltage of the drain electrode of the first transistor T1 may each be initialized to the initialization voltage VINT.

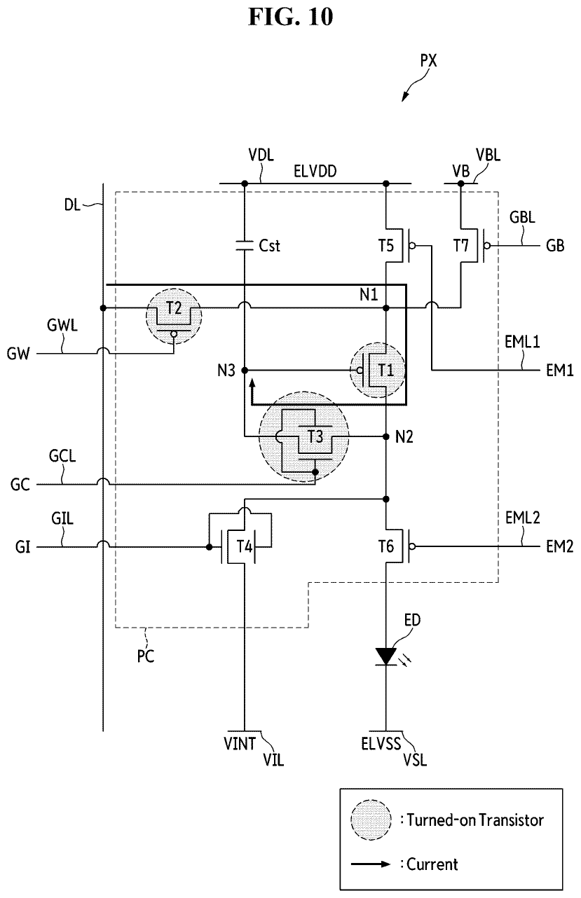

Next, the operation of a pixel PX in the fourth period P4 will be described as follows with reference to FIGS. 6 and 10.

FIG. 10 is a diagram for explaining the operation of the pixel PX of FIG. 5 in the fourth period P4 of FIG. 6.

As illustrated in FIG. 6, in the fourth period P4, the compensation gate signal GC and the write gate signal GW may each have an active level. In the fourth period P4, the first emission signal EM1, the second emission signal EM2, the initialization gate signal GI, and the bias gate signal GB may each have a non-active level. In addition, in the fourth period P4, a data voltage may be provided to the data line DL.

The write gate signal GW at the active level may be transmitted to the gate electrode of the second transistor T2 through the write gate line GWL. Accordingly, the second transistor T2 may be turned on.

The compensation gate signal GC at the active level may be transmitted to the gate electrode of the third transistor T3 through the compensation gate line GCL. Accordingly, the third transistor T3 may be turned on.

The initialization gate signal GI at the non-active level may be transmitted to the gate electrode of the fourth transistor T4 through the initialization gate line GIL. Accordingly, the fourth transistor T4 may be turned off.

The first emission signal EM1 at the non-active level may be transmitted to the gate electrode of the fifth transistor T5 through the first emission line EML1. Accordingly, the fifth transistor T5 may be turned off.

The second emission signal EM2 at the non-active level may be transmitted to the gate electrode of the sixth transistor T6 through the second emission line EML2. Accordingly, the sixth transistor T6 may be turned off.

The bias gate signal GB at the non-active level may be transmitted to the gate electrode of the seventh transistor T7 through the bias gate line GBL. Accordingly, the seventh transistor T7 may be turned off.

As the third transistor T3 is turned on as described above, the gate electrode (e.g., the third node N3) and the drain electrode (e.g., the second node N2) of the first transistor T1 may be electrically connected to each other. In other words, the first transistor T1 may be connected to the pixel circuit in a diode form.

As the second transistor T2 is turned on as described above, the data voltage from the data line DL may be applied to the source electrode (e.g., the first node N1) of the first transistor T1 through the turned-on second transistor T2. The voltage of the source electrode of the first transistor T1 may be maintained at the data voltage in this way, but the voltage of the gate electrode (e.g., the third node N3) of the first transistor T1 may gradually increase. In other words, as a current generated by the data voltage applied to the first node N1 is supplied to the second node N2 and the third node N3 through the turned-on first transistor T1, the voltage of the gate electrode of the first transistor T1 may gradually increase. As the voltage of the gate electrode of the first transistor T1 gradually increases, the gate-source voltage of the first transistor T1 may gradually decrease. When the decreasing gate-source voltage of the first transistor T1 reaches the threshold voltage of the first transistor T1, the first transistor T1 may be turned off. Therefore, the threshold voltage of the first transistor T1 may be detected at the time when the first transistor T1 is turned off, and the detected threshold voltage may be reflected in the third node N3. For example, the voltage of the third node N3 at the time when the first transistor T1 is turned off may be a voltage obtained by subtracting the threshold voltage of the first transistor T1 from the data voltage. The voltage of the third node N3 (e.g., the data voltage-the threshold voltage of the first transistor T1) may be stored by the capacitor Cst and maintained for a certain period of time. Therefore, in the fourth period P4, the threshold voltage of the first transistor T1 may be detected and maintained while the data voltage is applied. Thus, in the fourth period P4, the voltage of the third node N3 may include the threshold voltage of the first transistor T1.

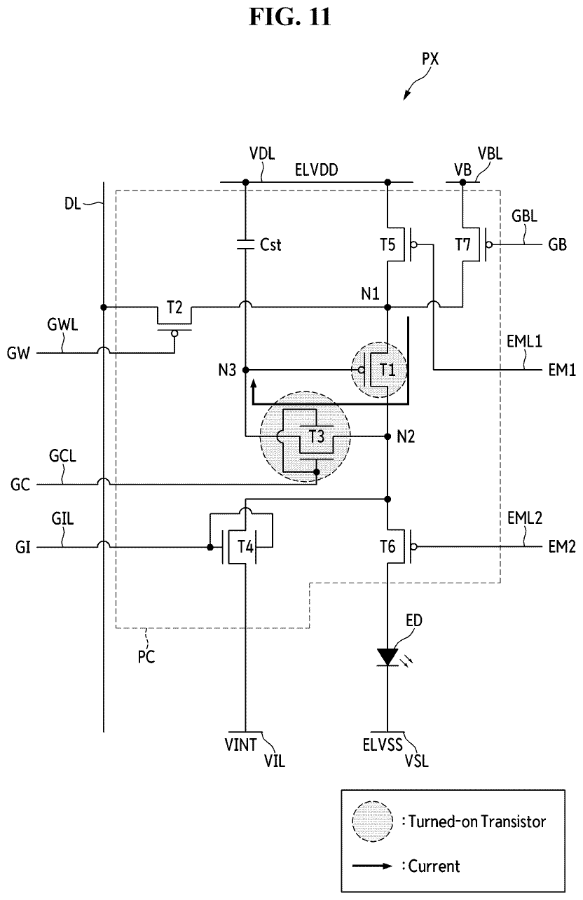

Next, the operation of a pixel PX in the fifth period P5 will be described as follows with reference to FIGS. 6 and 11.

FIG. 11 is a diagram for explaining the operation of the pixel PX of FIG. 5 in the fifth period P5 of FIG. 6.

As illustrated in FIG. 6, in the fifth period P5, the compensation gate signal GC may have an active level. In the fifth period P5, the first emission signal EM1, the second emission signal EM2, the initialization gate signal GI, the write gate signal GW, and the bias gate signal GB may each have a non-active level.

The compensation gate signal GC at the active level may be transmitted to the gate electrode of the third transistor T3 through the compensation gate line GCL. Accordingly, the third transistor T3 may be turned on.

The write gate signal GW at the non-active level may be transmitted to the gate electrode of the second transistor T2 through the write gate line GWL. Accordingly, the second transistor T2 may be turned off.

The initialization gate signal GI at the non-active level may be transmitted to the gate electrode of the fourth transistor T4 through the initialization gate line GIL. Accordingly, the fourth transistor T4 may be turned off.

The first emission signal EM1 at the non-active level may be transmitted to the gate electrode of the fifth transistor T5 through the first emission line EML1. Accordingly, the fifth transistor T5 may be turned off.

The second emission signal EM2 at the non-active level may be transmitted to the gate electrode of the sixth transistor T6 through the second emission line EML2. Accordingly, the sixth transistor T6 may be turned off.

The bias gate signal GB at the non-active level may be transmitted to the gate electrode of the seventh transistor T7 through the bias gate line GBL. Accordingly, the seventh transistor T7 may be turned off.

As the third transistor T3 is turned on as described above, the gate electrode (e.g., the third node N3) and the drain electrode (e.g., the second node N2) of the first transistor T1 may be electrically connected to each other. In other words, the first transistor T1 may be connected to the pixel circuit in a diode form.

The fifth period P5 may be a period for additionally detecting the threshold voltage of the first transistor T1. For example, when an active period of the write gate signal GW (e.g., a period during which the write gate signal GW is maintained at an active level) is not long enough for the threshold voltage of the first transistor T1 to be detected in the fourth period P4, the first transistor T1 may not be turned off but may remain turned on in the fourth period P4. In this case, the threshold voltage of the first transistor T1 may not be detected in the fourth period P4. Therefore, the third transistor T3 may be turned on once more in the fifth period P5, so that the first transistor T1 is connected to the pixel circuit in a diode form. Then, the voltage of the third node N3 may increase sufficiently through the turned-on first transistor T1. Accordingly, the first transistor T1 may be turned off in the fifth period P5, and thus the threshold voltage of the first transistor T1 may be detected.

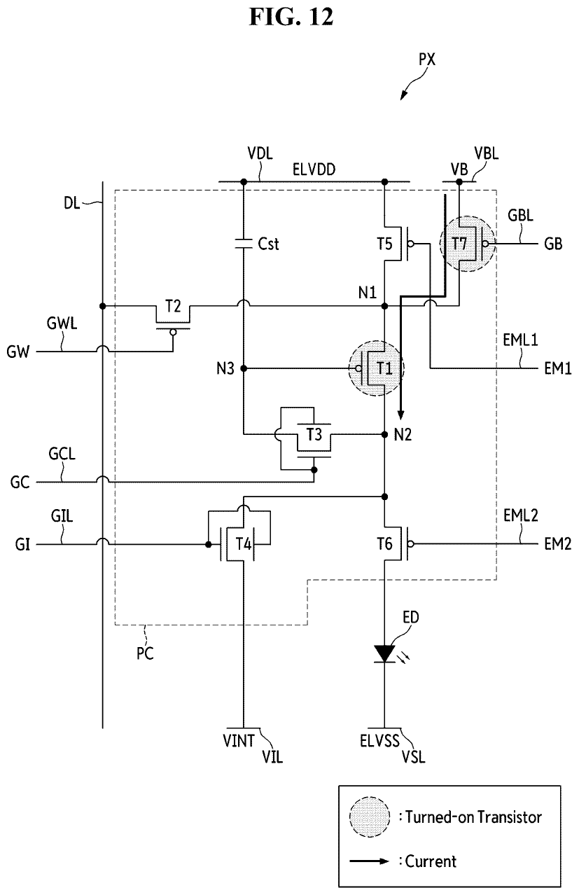

Next, the operation of a pixel PX in the sixth period P6 will be described as follows with reference to FIGS. 6 and 12.

FIG. 12 is a diagram for explaining the operation of the pixel PX of FIG. 5 in the sixth period P6 of FIG. 6.

As illustrated in FIG. 6, in the sixth period P6, the bias gate signal GB may have an active level. In the sixth period P6, the first emission signal EM1, the second emission signal EM2, the initialization gate signal GI, the compensation gate signal GC, and the write gate signal GW may each have a non-active level.

The bias gate signal GB at the active level may be transmitted to the gate electrode of the seventh transistor T7 through the bias gate line GBL. Accordingly, the seventh transistor T7 may be turned on.

The write gate signal GW at the non-active level may be transmitted to the gate electrode of the second transistor T2 through the write gate line GWL. Accordingly, the second transistor T2 may be turned off.

The compensation gate signal GC at the non-active level may be transmitted to the gate electrode of the third transistor T3 through the compensation gate line GCL. Accordingly, the third transistor T3 may be turned off.

The initialization gate signal GI at the non-active level may be transmitted to the gate electrode of the fourth transistor T4 through the initialization gate line GIL. Accordingly, the fourth transistor T4 may be turned off.

The first emission signal EM1 at the non-active level may be transmitted to the gate electrode of the fifth transistor T5 through the first emission line EML1. Accordingly, the fifth transistor T5 may be turned off.

The second emission signal EM2 at the non-active level may be transmitted to the gate electrode of the sixth transistor T6 through the second emission line EML2. Accordingly, the sixth transistor T6 may be turned off.

As the seventh transistor T7 is turned on as described above, the bias voltage VB from the bias voltage line VBL may be applied to the source electrode (e.g., the first node N1) of the first transistor T1 through the turned-on seventh transistor T7. Accordingly, the voltage of the source electrode of the first transistor T1 may gradually increase, and thus the gate-source voltage of the first transistor T1 may become greater than the threshold voltage of the first transistor T1. Therefore, the first transistor T1 may be turned on. The bias voltage VB from the bias voltage line VBL may be applied to the first node N1 and the second node N2 through the turned-on first transistor T1. Here, the voltage of the second node N2 may be a difference voltage obtained by subtracting the threshold voltage of the first transistor T1 from the bias voltage VB. Accordingly, the hysteresis of the first transistor T1 can be improved in the sixth period P6. Therefore, even when a scanning rate of the display device 10 changes rapidly, the deviation of the driving current Isd flowing through the first transistor T1 can be reduced or minimized, thereby improving the image quality of the display device 10.

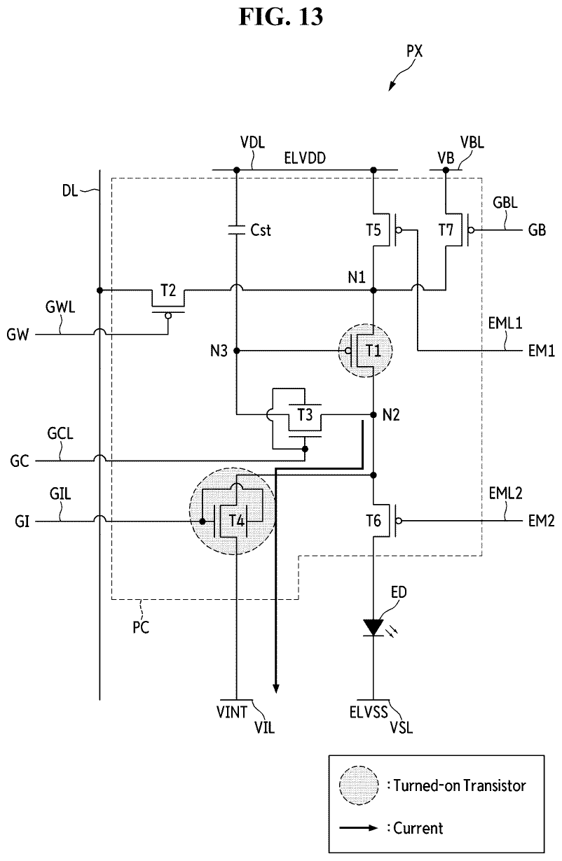

Next, the operation of a pixel PX in the seventh period P7 will be described as follows with reference to FIGS. 6 and 13.

FIG. 13 is a diagram for explaining the operation of the pixel PX of FIG. 5 in the seventh period P7 of FIG. 6.

As illustrated in FIG. 6, in the seventh period P7, the initialization gate signal GI may have an active level. In the seventh period P7, the first emission signal EM1, the second emission signal EM2, the compensation gate signal GC, the write gate signal GW, and the bias gate signal GB may each have a non-active level.

The initialization gate signal GI at the active level may be transmitted to the gate electrode of the fourth transistor T4 through the initialization gate line GIL. Accordingly, the fourth transistor T4 may be turned on.

The write gate signal GW at the non-active level may be transmitted to the gate electrode of the second transistor T2 through the write gate line GWL. Accordingly, the second transistor T2 may be turned off.

The compensation gate signal GC at the non-active level may be transmitted to the gate electrode of the third transistor T3 through the compensation gate line GCL. Accordingly, the third transistor T3 may be turned off.

The first emission signal EM1 at the non-active level may be transmitted to the gate electrode of the fifth transistor T5 through the first emission line EML1. Accordingly, the fifth transistor T5 may be turned off.

The second emission signal EM2 at the non-active level may be transmitted to the gate electrode of the sixth transistor T6 through the second emission line EML2. Accordingly, the sixth transistor T6 may be turned off.

The bias gate signal GB at the non-active level may be transmitted to the gate electrode of the seventh transistor T7 through the bias gate line GBL. Accordingly, the seventh transistor T7 may be turned off.

As the fourth transistor T4 is turned on as described above, the initialization voltage VINT from the initialization voltage line VIL may be applied to the drain electrode of the first transistor T1 (e.g., the second node N2) through the turned-on fourth transistor T4. Accordingly, the voltage of the drain electrode of the first transistor T1 may be discharged to the initialization voltage VINT. Accordingly, the voltage of the second node N2 may be maintained at a low voltage during the seventh period P7. Because the voltage of the second node N2 is maintained low at the same voltage as the initialization voltage VINT during the seventh period P7, even when a gray level of the data voltage changes rapidly from a white gray level to a black gray level, the light-emitting element ED can be turned off at a sufficiently fast speed in a next period (e.g., the eighth period P8). Therefore, even when an image changes rapidly from the white gray level to the black gray level, an image corresponding to the black gray can be accurately expressed.

In other words, to improve the hysteresis of the first transistor T1 described above, the second node N2 must be maintained at a high voltage (e.g., the bias voltage-the threshold voltage of the first transistor T1) in a previous period (e.g., the sixth period P6). In this case, it may be difficult to normally express the black gray level when the gray level changes from the white gray level to the black gray level. To solve this problem, the voltage of the second node N2 may be discharged to a low voltage (e.g., the initialization voltage VINT) in advance in the seventh period P7 prior to an emission period (e.g., the eighth period P8).

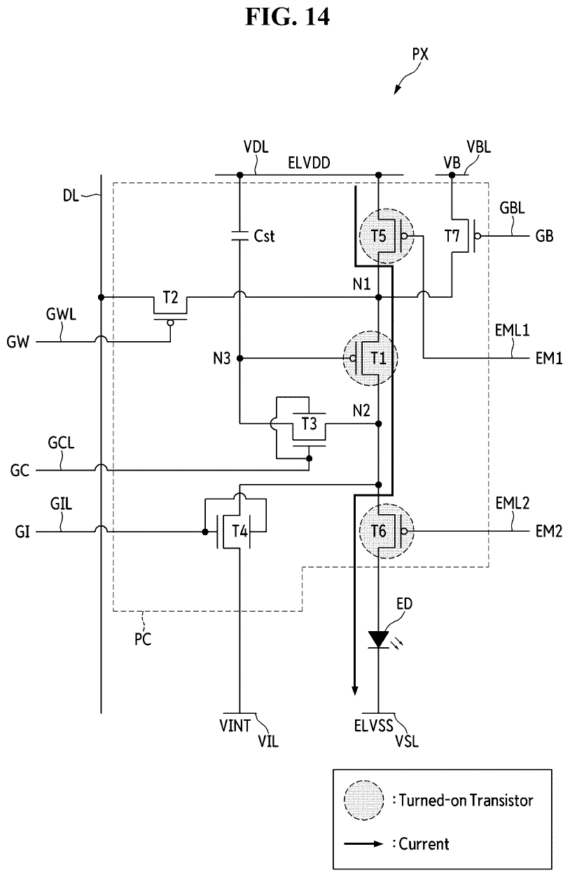

Next, the operation of a pixel PX in the eighth period P8 will be described as follows with reference to FIGS. 6 and 14.

FIG. 14 is a diagram for explaining the operation of the pixel PX of FIG. 5 in the eighth period P8 of FIG. 6.

As illustrated in FIG. 6, in the eighth period P8, the first emission signal EM1 and the second emission signal EM2 may each have an active level. In the eighth period P8, the initialization gate signal GI, the compensation gate signal GC, the write gate signal GW, and the bias gate signal GB may each have a non-active level.

The first emission signal EM1 at the active level may be transmitted to the gate electrode of the fifth transistor T5 through the first emission line EML1. Accordingly, the fifth transistor T5 may be turned on.

The second emission signal EM2 at the active level may be transmitted to the gate electrode of the sixth transistor T6 through the second emission line EML2. Accordingly, the sixth transistor T6 may be turned on.

The write gate signal GW at the non-active level may be transmitted to the gate electrode of the second transistor T2 through the write gate line GWL. Accordingly, the second transistor T2 may be turned off.

The compensation gate signal GC at the non-active level may be transmitted to the gate electrode of the third transistor T3 through the compensation gate line GCL. Accordingly, the third transistor T3 may be turned off.

The initialization gate signal GI at the non-active level may be transmitted to the gate electrode of the fourth transistor T4 through the initialization gate line GIL. Accordingly, the fourth transistor T4 may be turned off.

The bias gate signal GB at the non-active level may be transmitted to the gate electrode of the seventh transistor T7 through the bias gate line GBL. Accordingly, the seventh transistor T7 may be turned off.

Meanwhile, the first transistor T1 may be kept turned on by the gate-source voltage maintained by the capacitor Cst.

In the eighth period P8, as the first transistor T1, the fifth transistor T5, and the sixth transistor T6 are turned on, the driving current Isd may be supplied to the light-emitting element ED through the turned-on first transistor T1, fifth transistor T5 and sixth transistor T6. Therefore, the light-emitting element ED may emit light according to the driving current Isd. Here, the gate-source voltage maintained by the capacitor Cst includes the threshold voltage of the first transistor T1. Thus, the magnitude of the driving current Isd flowing to the light-emitting element ED through the turned-on first transistor T1 may be determined based on the data voltage and the threshold voltage of the first transistor T1. Therefore, the driving current Isd supplied to the light-emitting element ED may accurately reflect the magnitude of the data voltage. In this way, because the driving current Isd of each pixel PX is determined by compensating for different threshold voltages of the first transistors T1 of the pixels PX, a difference in luminance between the pixels PX due to a difference in threshold voltage between the first transistors T1 of the pixels PX can be reduced or minimized. Therefore, the image quality of the display device 10 can be improved.

According to one or more embodiments, because the voltage of the second node N2 is discharged to the initialization voltage VINT and is thus maintained at a low voltage in a previous period (e.g., the seventh period P7), a voltage difference between the anode of the light-emitting element ED (e.g., the anode connected to the source electrode of the sixth transistor T6) and the cathode of the light-emitting element ED may be maintained relatively small in the eighth period P8. In other words, the voltage of the anode of the light-emitting element ED may be kept sufficiently low during the eighth period P8. Therefore, as described above, even when the gray level of the data voltage changes rapidly from a white gray level to a black gray level in adjacent frame periods, the voltage of the anode of the light-emitting element ED can be lowered at fast speed. Therefore, an image of the black gray level can be accurately expressed.

On the other hand, when the gray level changes from the black gray level to the white gray level, because the first transistor T1 is already turned on by the data voltage of the white gray level to allow a large amount of current to flow, the voltage of the anode of the light-emitting element ED can be increased sufficiently rapidly from the black gray level to a large voltage corresponding to the white gray level even when the voltage of the second node N2 is discharged to a low voltage such as the initialization voltage VINT. Therefore, the image quality of the display device 10 can be improved. In addition, because the black gray level can be improved in this way, a swing width of the data voltage can be reduced, thereby improving the power consumption of the display device 10.

In addition, according to one or more embodiments, because the fourth transistor T4 is located between the drain electrode of the first transistor T1 and the initialization voltage line VIL, a voltage difference between the voltage of the drain electrode of the first transistor T1 and the initialization voltage VINT is low.

Therefore, a leakage current (e.g., an off leakage current) of the fourth transistor T4 can be reduced or minimized. Accordingly, an image can be displayed without flicker even when the display device 10 is driven at a low frequency.

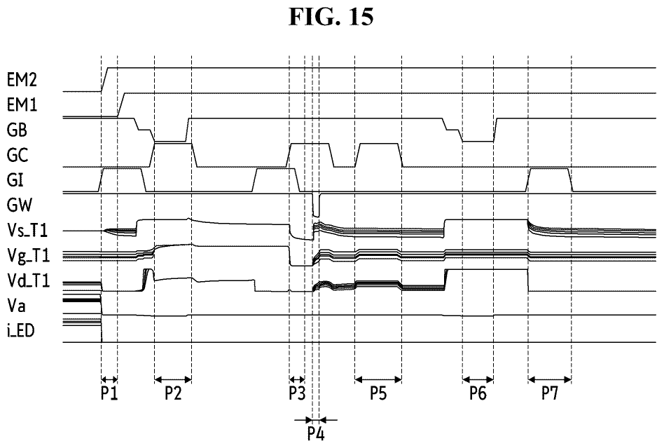

FIG. 15 shows simulated waveforms of the first emission signal EM1, the second emission signal EM2, the bias gate signal GB, the compensation gate signal GC, the initialization gate signal GI, the write gate signal GW, a voltage Vs_T1 of the source electrode of the first transistor T1, a voltage Vg_T1 of the gate electrode of the first transistor T1, a voltage Vd_T1 of the drain electrode of the first transistor T1, a voltage Va of the anode of the light-emitting element ED, and a current i_ED of the light-emitting element ED.

The first emission signal EM1, the second emission signal EM2, the bias gate signal GB, the compensation gate signal GC, the initialization gate signal GI, and the write gate signal GW of FIG. 15 may respectively correspond to the first emission signal EM1, the second emission signal EM2, the bias gate signal GB, the compensation gate signal GC, the initialization gate signal GI, and the write gate signal GW of FIG. 6 described above.

The voltage Vs_T1 of the source electrode of the first transistor T1, the voltage Vg_T1 of the gate electrode of the first transistor T1, the voltage Vd_T1 of the drain electrode of the first transistor T1, the voltage Va of the anode of the light-emitting element ED, and the current i_ED of the light-emitting element ED may change according to the above signals in each of the first period P1, the second period P2, the third period P3, the fourth period P4, the fifth period P5, the sixth period P6, and the seventh period P7.

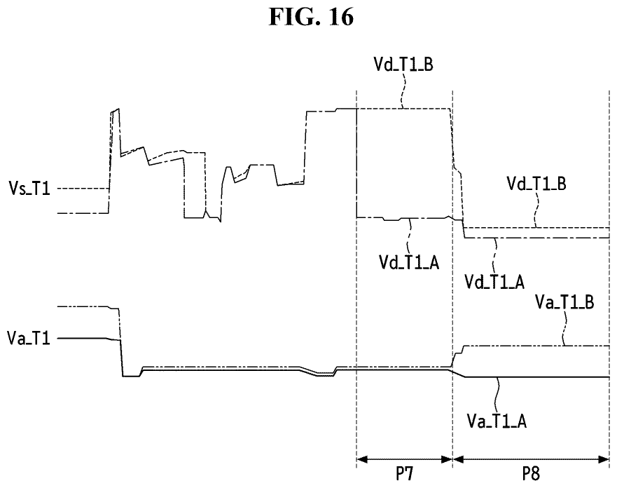

FIG. 16 shows simulated waveforms for explaining an aspect of the display device 10 according to one or more embodiments.

FIG. 16 shows a simulated waveform of the voltage Vd_T1 (hereinafter, referred to as a drain voltage) of the drain electrode (e.g., the second node N2) of the first transistor T1 and a simulated waveform of the voltage Va_T1 (hereinafter, referred to as an anode voltage) of the anode of the light-emitting element ED.

In FIG. 16, the drain voltage Vd_T1 may be divided into a first drain voltage Vd_T1_A and a second drain voltage Vd_T1_B. For example, the first drain voltage Vd_T1_A may be a drain voltage of the first transistor T1 detected in a first pixel including the fourth transistor T4, and the second drain voltage Vd_T1_B may be a drain voltage of the first transistor T1 detected in a second pixel not including the fourth transistor T4.

In FIG. 16, the anode voltage Va_T1 may be divided into a first anode voltage Va_T1_A and a second anode voltage Va_T1_B. For example, the first anode voltage Va_T1_A may be a voltage of the anode detected in the first pixel including the fourth transistor T4, and the second anode voltage Va_T1_B may be a voltage of the anode detected in the second pixel not including the fourth transistor T4.

As shown in FIG. 16, the first drain voltage Vd_T1_A may drop to a significantly low voltage in the seventh period P7. This is because the initialization voltage VINT is applied to the second node N2 through the fourth transistor T4 turned on in the seventh period P7 as described above. On the other hand, the second drain voltage Vd_T1_B may be maintained at a relatively high voltage.

As shown in FIG. 16, as the sixth transistor T6 is turned on in the eighth period P8, a drain voltage (e.g., the first drain voltage Vd_T1_A or the second drain voltage Vd_T1_B) may be applied to the anode of the light-emitting element ED. In the eighth period P8, the first anode voltage Va_T1_A may drop to a low voltage corresponding to almost a black gray level. This is because the first anode voltage Va_T1_A has already dropped to a low voltage in the seventh period P7 as described above. On the other hand, the second anode voltage Va_T1_B may be maintained at a higher voltage than the first anode voltage Va_T1_A in the eighth period P8. This is because the second drain voltage Va_T1_B is maintained at a relatively high voltage without being discharged in the seventh period P7.

Therefore, even when the gray level of a data voltage changes rapidly from a white gray level to a black gray level, the light-emitting element ED of the first pixel (e.g., the first pixel including the fourth transistor T4) can be turned off at a sufficiently fast speed in the eighth period P8. Therefore, the display device according to one or more embodiments including the first pixel can accurately express an image corresponding to the black gray level even when the image changes rapidly from the white gray level to the black gray level.

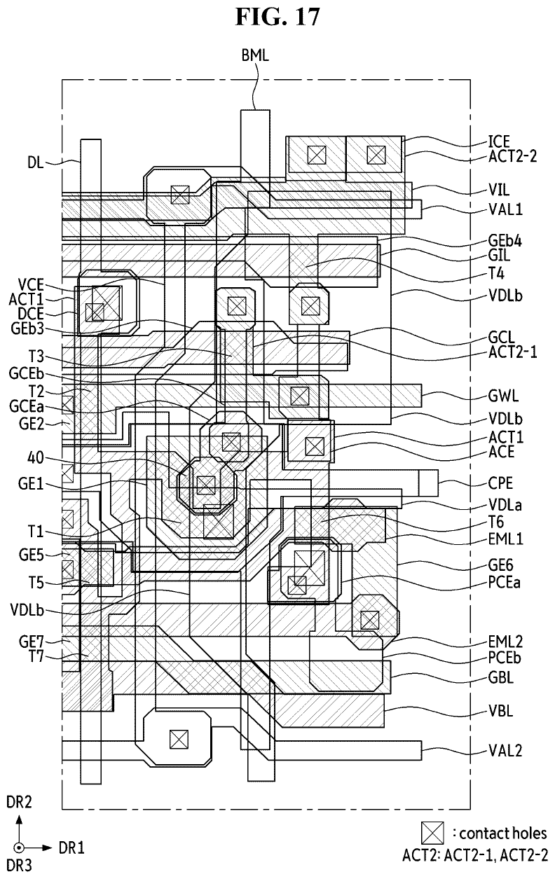

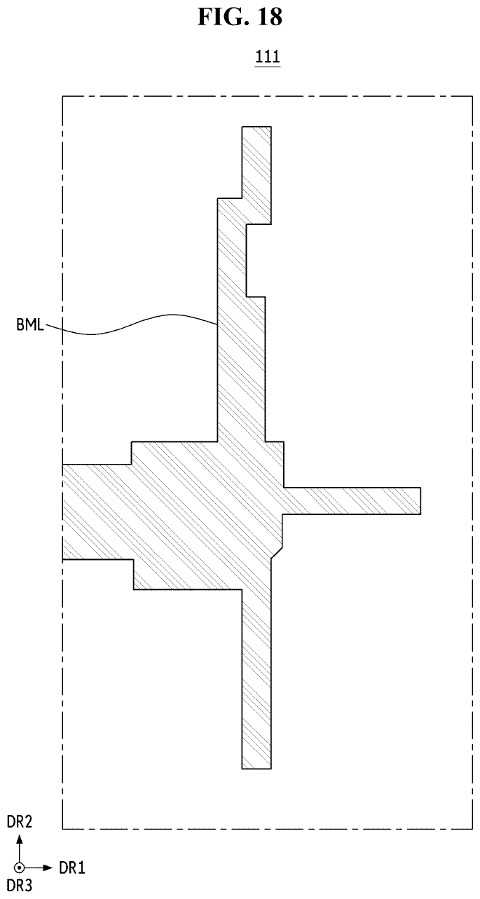

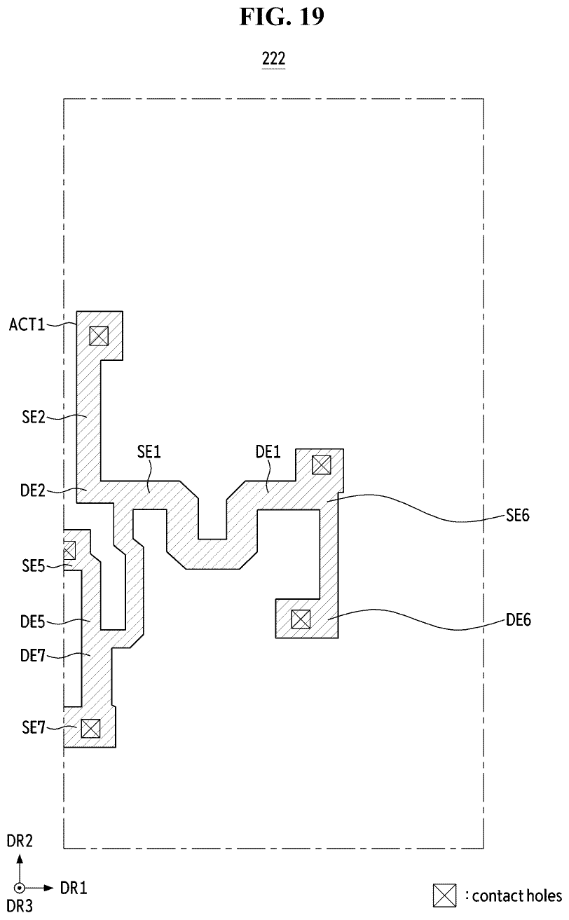

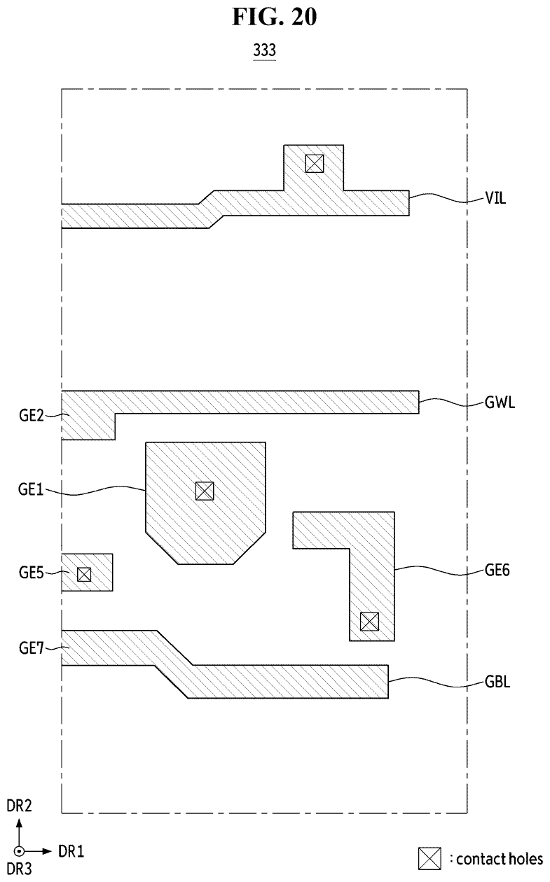

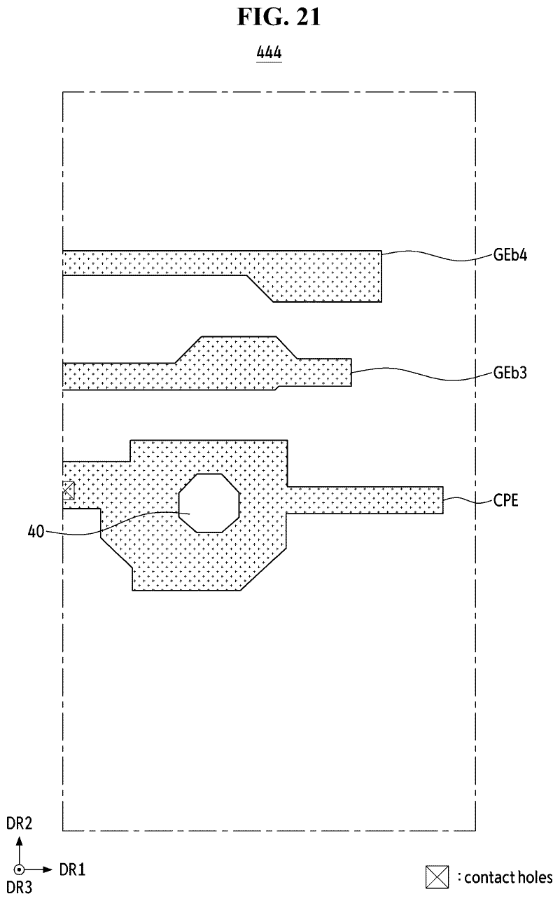

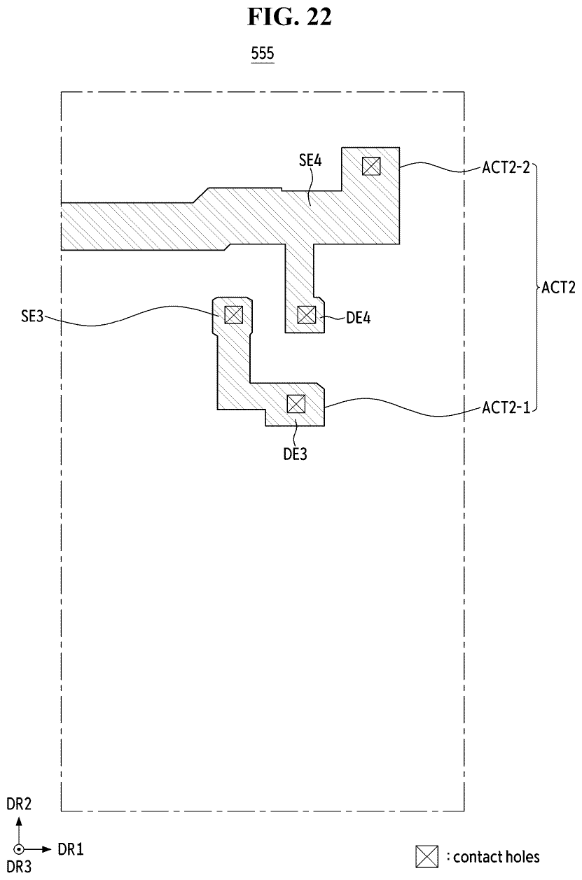

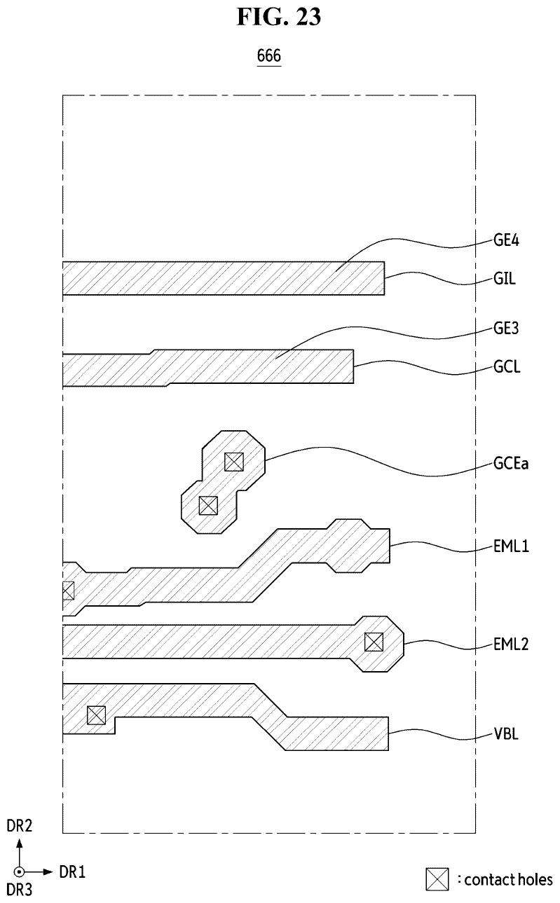

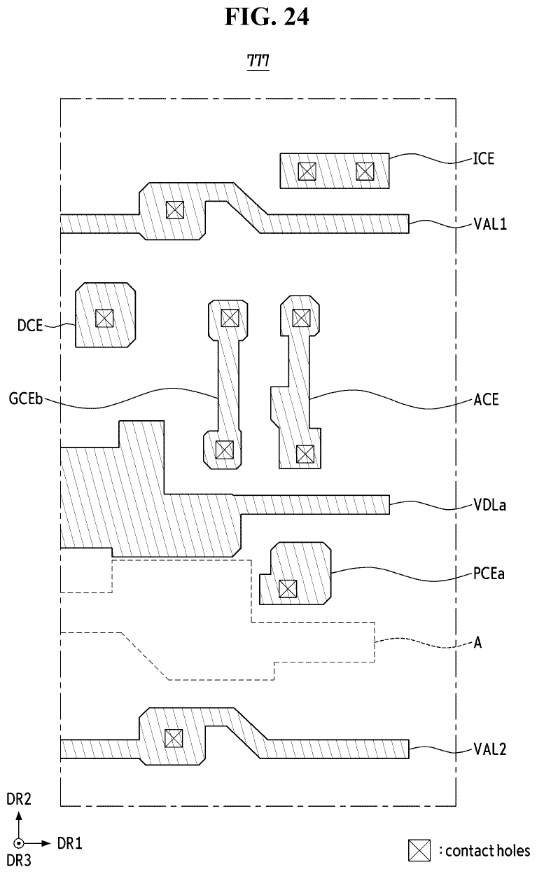

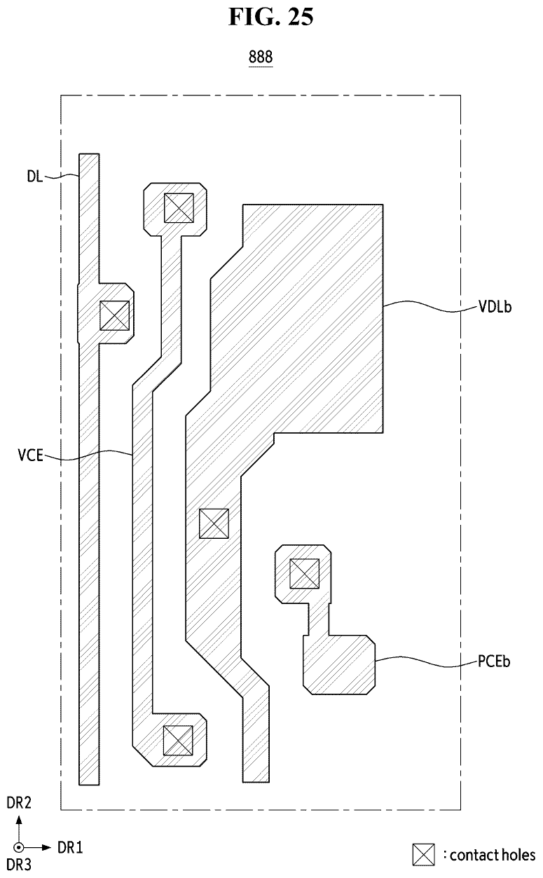

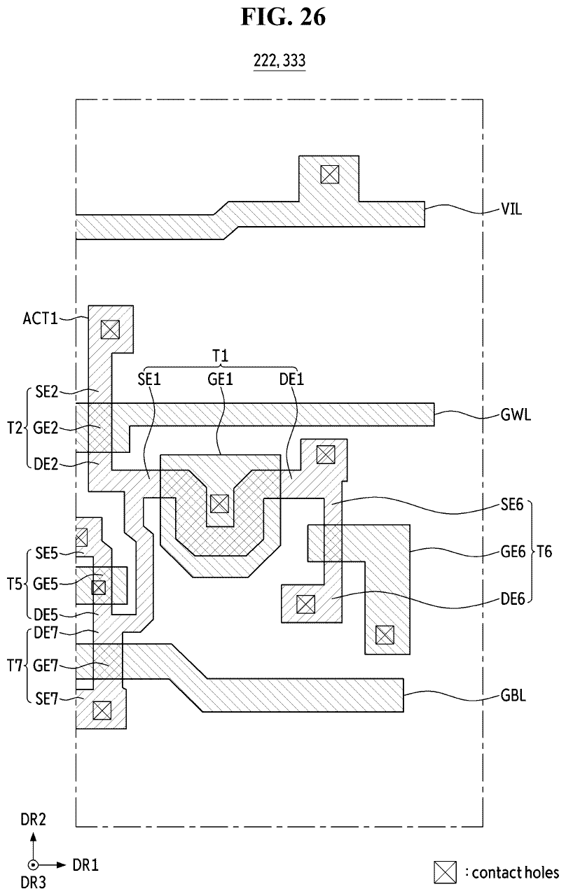

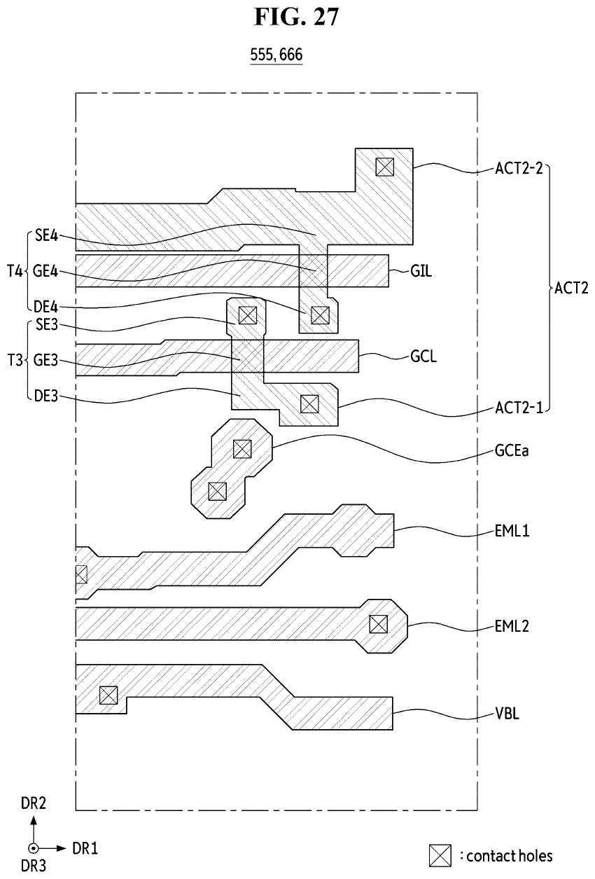

FIG. 17 is a plan view of a pixel array of the display device according to one or more embodiments. FIG. 18 is a plan view of only a first pattern layer 111 of FIG. 17. FIG. 19 is a plan view of only a second pattern layer 222 of FIG. 17. FIG. 20 is a plan view of only a third pattern layer 333 of FIG. 17. FIG. 21 is a plan view of only a fourth pattern layer 444 of FIG. 17. FIG. 22 is a plan view of only a fifth pattern layer 555 of FIG. 17. FIG. 23 is a plan view of only a sixth pattern layer 666 of FIG. 17. FIG. 24 is a plan view of only a seventh pattern layer 777 of FIG. 17. FIG. 25 is a plan view of only an eighth pattern layer 888 of FIG. 17. FIG. 26 is a plan view of only the second pattern layer 222 and the third pattern layer 333 of FIG. 17. FIG. 27 is a plan view of only the fifth pattern layer 555 and the sixth pattern layer 666 of FIG. 17.

The first pattern layer 111 may be located on a substrate SUB along the third direction DR3. The first pattern layer 111 may include a light-blocking layer BML as in the example illustrated in FIGS. 17 and 18. The light-blocking layer BML may be located on the substrate SUB to cover an overlap region (e.g., a channel region of the first transistor T1) between a first gate electrode GE1 and a first active layer ACT1. In other words, the light-blocking layer BML may be located on a barrier layer BR to overlap the channel region of the first transistor T1, which is a driving transistor.

The light-blocking layer BML may be made of a metal material such as chromium (Cr) or molybdenum (Mo) or may be made of black ink or black dye. When the light-blocking layer BML is made of a metal material, it may be supplied with constant power. Accordingly, the light-blocking layer BML may not electrically float, and the electrical characteristics of a transistor (e.g., the first transistor T1) on the light-blocking layer BML can be stabilized.

The second pattern layer 222 may be located on the first pattern layer 111 along the third direction DR3. The second pattern layer 222 may include the first active layer ACT1 as in the example illustrated in FIGS. 17 and 19.

The first active layer ACT1 may provide source electrodes SE1, SE2, SE5, SE6, and SE7 and drain electrodes DE1, DE2, DE5, DE6, and DE7 of the first transistor T1, the second transistor T2, the fifth transistor T5, the sixth transistor T6, and the seventh transistor T7.

The first active layer ACT1 may be a semiconductor layer made of low temperature polycrystalline silicon (LTPS).

The third pattern layer 333 may be located on the second pattern layer 222 along the third direction DR3. An insulating layer may be located between the second pattern layer 222 and the third pattern layer 333. The third pattern layer 333 may include, as in the example illustrated in FIGS. 17 and 20, the first gate electrode GE1, a second gate electrode GE2, a fifth gate electrode GE5, a sixth gate electrode GE6, a seventh gate electrode GE7, the write gate line GWL, the initialization voltage line VIL, and the bias gate line GBL.

The write gate line GWL may include the second gate electrode GE2. For example, a part of the write gate line GWL may correspond to the second gate electrode GE2. The write gate line GWL and the second gate electrode GE2 may be formed integrally with each other.

The bias gate line GBL may include the seventh gate electrode GE7. For example, a part of the bias gate line GBL may correspond to the seventh gate electrode GE7. The bias gate line GBL and the seventh gate electrode GE7 may be formed integrally with each other.

As illustrated in FIGS. 17 and 26, the first, second, fifth, sixth, and seventh gate electrodes GE1, GE2, GE5, GE6, and GE7 may overlap the first active layer ACT1. Channel regions of the first, second, fifth, sixth, and seventh transistors T1, T2, T5, T6, and T7 may be formed in overlap regions between the first, second, fifth, sixth and seventh gate electrodes GE1, GE2, GE5, GE6, and GE7 and the first active layer ACT1.

As illustrated in FIG. 26, the first transistor T1 may include the first gate electrode GE1, the first source electrode SE1, and the first drain electrode DE1.

The second transistor T2 may include the second gate electrode GE2, the second source electrode SE2, and the second drain electrode DE2.

The fifth transistor T5 may include the fifth gate electrode GE5, the fifth source electrode SE5, and the fifth drain electrode DE5.

The sixth transistor T6 may include the sixth gate electrode GE6, the sixth source electrode SE6, and the sixth drain electrode DE6.

The seventh transistor T7 may include the seventh gate electrode GE7, the seventh source electrode SE7, and the seventh drain electrode DE7.

The fourth pattern layer 444 may be located on the third pattern layer 333 along the third direction DR3. An insulating layer may be located between the third pattern layer 333 and the fourth pattern layer 444. The fourth pattern layer 444 may include, as in the example illustrated in FIGS. 17 and 21, a third counter gate electrode GEb3, a fourth counter gate electrode GEb4, and a capacitor electrode CPE.

The third counter gate electrode GEb3 may overlap a (2-1)^{th} active layer ACT2-1 and a third gate electrode GE3 as in the example illustrated in FIG. 17. For example, the third counter gate electrode GEb3 may face the third gate electrode GE3 with the (2-1)^{th} active layer ACT2-1 interposed between them.

The fourth counter gate electrode GEb4 may overlap a (2-2)^{th} active layer ACT2-2 and a fourth gate electrode GE4 as in the example illustrated in FIG. 17. For example, the fourth counter gate electrode GEb4 may face the fourth gate electrode GE4 with the (2-2)^{th} active layer ACT2-2 interposed between them.

The capacitor electrode CPE may overlap the first gate electrode GE1 as illustrated in FIG. 17. The capacitor Cst may be formed in an overlap region between the capacitor electrode CPE and the first gate electrode GE1. For example, the first gate electrode GE1 and the capacitor electrode CPE may correspond to the first electrode and the second electrode of the capacitor Cst, respectively. In addition, the capacitor electrode CPE may have/define a hole 40 penetrating therethrough in the third direction DR3. The first gate electrode GE1 may be connected to a third source electrode SE3 of the third transistor T3 through the hole 40 of the capacitor electrode CPE, a lower gate connection electrode GCEa, and an upper gate connection electrode GCEb. In addition, the capacitor electrode CPE may be connected to the fifth source electrode SE5 of the fifth transistor T5 through a lower driving voltage line VDLa, which will be described later.

The fifth pattern layer 555 may be located on the fourth pattern layer 444 along the third direction DR3. An insulating layer may be located between the fourth pattern layer 444 and the fifth pattern layer 555. The fifth pattern layer 555 may include a second active layer ACT2 as in the example illustrated in FIGS. 17 and 22. The second active layer ACT2 may include the (2-1)^{th} active layer ACT2-1 and the (2-2)^{th}active layer ACT2-2.

The (2-1)^{th} active layer ACT2-1 may provide a channel region, the third source electrode SE3, and a third drain electrode DE3 of the third transistor T3. The (2-2)^{th} active layer ACT2-2 may provide a channel region, a fourth source electrode SE4, and a fourth drain electrode DE4 of the fourth transistor T4.

The second active layer ACT2 may be, for example, an oxide-based semiconductor.

The sixth pattern layer 666 may be located on the fifth pattern layer 555 along the third direction DR3. An insulating layer may be located between the fifth pattern layer 555 and the sixth pattern layer 666. The sixth pattern layer 666 may include, as in the example illustrated in FIGS. 17 and 23, the third gate electrode GE3, the fourth gate electrode GE4, the lower gate connection electrode GCEa, the compensation gate line GCL, the initialization gate line GIL, the first emission line EML1, the second emission line EML2, and the bias voltage line VBL.

As illustrated in FIGS. 17 and 27, the third gate electrode GE3 may overlap the (2-1)^{th} active layer ACT2-1 , and the fourth gate electrode GE4 may overlap the (2-2)^{th} active layer ACT2-2. The channel regions of the third and fourth transistors T3 and T4 may be formed in overlap regions between the third and fourth gate electrodes GE3 and GE4 and the (2-1)^{th} and (2-2)^{th} active layers ACT2-1 and ACT2-2.

The third transistor T3 may include the third gate electrode GE3, the third source electrode SE3, and the third drain electrode DE3.

The fourth transistor T4 may include the fourth gate electrode GE4, the fourth source electrode SE4, and the fourth drain electrode DE4.

The lower gate connection electrode GCEa may be connected to the first gate electrode GE1 through a contact hole of the insulating layer and the hole 40 of the capacitor connection electrode CPE.

The compensation gate line GCL may include the third gate electrode GE3. For example, a part of the compensation gate line GCL may correspond to the third gate electrode GE3. The compensation gate line GCL and the third gate electrode GE3 may be formed integrally with each other.

The initialization gate line GIL may include the fourth gate electrode GE4. For example, a part of the initialization gate line GIL may correspond to the fourth gate electrode GE4. The initialization gate line GIL and the fourth gate electrode GE4 may be formed integrally with each other.

The first emission line EML1 may be connected to the fifth gate electrode GE5 through a contact hole of the insulating layer.

The second emission line EML2 may be connected to the sixth gate electrode GE6 through a contact hole of the insulating layer.

The bias voltage line VBL may be connected to the seventh source electrode SE7 through a contact hole of the insulating layer.

The seventh pattern layer 777 may be located on the sixth pattern layer 666 along the third direction DR3. An insulating layer may be located between the sixth pattern layer 666 and the seventh pattern layer 777. The seventh pattern layer 777 may include, as in the example illustrated in FIGS. 17 and 24, the lower driving voltage line VDLa, a first auxiliary line VAL1, a second auxiliary line VAL2, the upper gate connection electrode GCEb, a lower anode connection electrode PCEa, an active connection electrode ACE, and an initialization connection electrode ICE.

The lower driving voltage line VDLa may overlap the capacitor electrode CPE and the first gate electrode GE1. A side of the lower driving voltage line VDLa may be connected to the capacitor electrode CPE through a contact hole of the insulating layer. The other side of the lower driving voltage line VDLa may be connected to the fifth source electrode SE5 through a contact hole of the insulating layer. The lower driving voltage line VDLa may be connected to an upper driving voltage line VDLb, which will be described later. The lower driving voltage line VDLa and the upper driving voltage line VDLb may be connected to each other to form the driving voltage line VDL described above. For example, the driving voltage line VDL may include a plurality of lower driving voltage lines VDLa extending in a horizontal direction (e.g., the first direction DR1) and a plurality of upper driving voltage lines VDLb extending in a vertical direction (e.g., the second direction DR2). The driving voltage line VDL including the lower driving voltage lines VDLa and the upper driving voltage lines VDLb may have a mesh shape.

A side of the first auxiliary line VAL1 may be connected to the lower driving voltage line VDLa within the data driver 220.

A side of the second auxiliary line VAL2 may be connected to the lower driving voltage line VDLa within the data driver 220.

A side of the upper gate connection electrode GCEb may be connected to the lower gate connection electrode GCEa through a contact hole of the insulating layer. The other side of the upper gate connection electrode GCEb may be connected to the third source electrode SE3 through a contact hole of the insulating layer.

A side of the active connection electrode ACE may be connected to the sixth source electrode SE6 of the first active layer ACT1 through a contact hole of the insulating layer. The other side of the active connection electrode ACE may be connected to the fourth drain electrode DE4 of the (2-2)^{th} active layer ACT2-2.

The lower anode connection electrode PCEa may be connected to the sixth drain electrode DE6 through a contact hole of the insulating layer.

A data connection electrode DCE may be connected to the second source electrode SE2 through a contact hole of the insulating layer.

A side of the initialization connection electrode ICE may be connected to the initialization voltage line VIL through a contact hole of the insulating layer. The other side of the initialization connection electrode ICE may be connected to the fourth drain electrode DE4 through a contact hole of the insulating layer.

The eighth pattern layer 888 may be located on the seventh pattern layer 777 along the third direction DR3. An insulating layer may be located between the seventh pattern layer 777 and the eighth pattern layer 888. The eighth pattern layer 888 may include, as in the example illustrated in FIGS. 17 and 25, the data line DL, a line connection electrode VCE, the upper driving voltage line VDLb, and an upper anode connection electrode PCEb.

The data line DL may be connected to the data connection electrode DCE through a contact hole of the insulating layer.

A side of the line connection electrode VCE may be connected to the first auxiliary line VAL1 through a contact hole of the insulating layer. The other side of the line connection electrode VCE may be connected to the second auxiliary line VAL2 through a contact hole of the insulating layer.

The upper driving voltage line VDLb may be connected to the lower driving voltage line VDLa through a contact hole of the insulating layer.

The upper anode connection electrode PCEb may be connected to the lower anode connection electrode PCEa through a contact hole of the insulating layer.

In one or more embodiments, a ninth pattern layer may be located on the eighth pattern layer 888 with an insulating layer between them. The ninth pattern layer may include, for example, an anode. The anode may be connected to the upper anode connection electrode PCEb through a contact hole of the insulating layer.

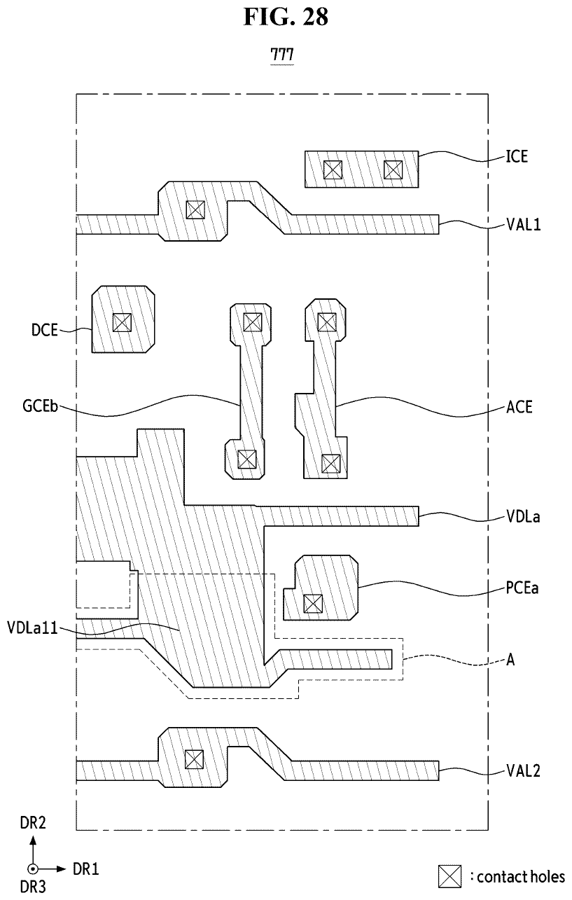

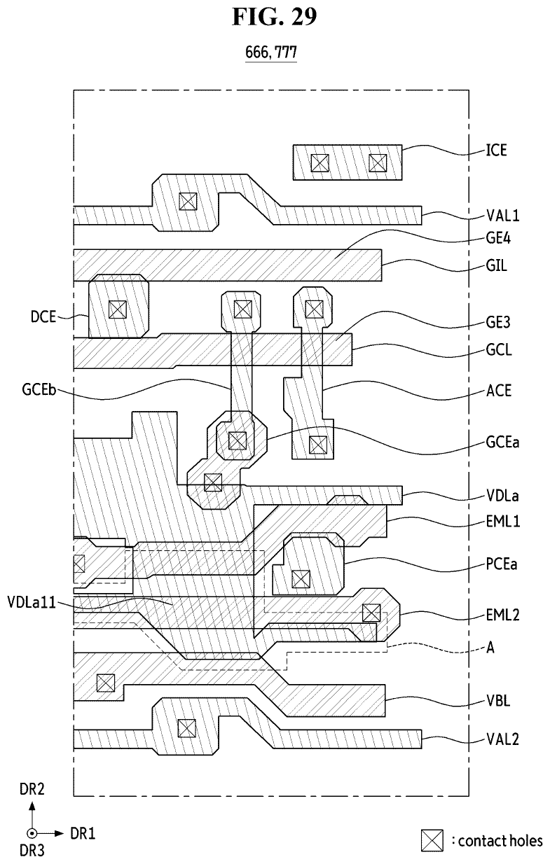

FIG. 28 is a plan view of a seventh pattern layer 777 of a display device according to one or more embodiments. FIG. 29 is a plan view of the sixth pattern layer 666 of FIG. 23 and the seventh pattern layer 777 of FIG. 28.

The seventh pattern layer 777 of FIG. 28 is different from the seventh pattern layer 777 of FIG. 24 described above in the shape of a lower driving voltage line VDLa. Therefore, this difference will be mainly described as follows.

As illustrated in FIG. 28, the lower driving voltage line VDLa may be extended further toward a second auxiliary line VAL2. According to one or more embodiments, a voltage of a gate electrode (e.g., a first node N1) of a first transistor T1 and a voltage of an anode (e.g., a drain electrode of a sixth transistor T6) of a light-emitting element ED may be initialized through one transistor (e.g., a fourth transistor T4). Therefore, according to one or more embodiments, the number of transistors included in a pixel PX can be reduced, which, in turn, increases an idle area A of the pixel PX. For example, as illustrated in FIG. 24, the idle area A may exist below the lower driving voltage line VDLa. Therefore, as illustrated in FIG. 28, the area of the lower driving voltage line VDLa may be expanded by utilizing the idle area A. For example, the lower driving voltage line VDLa may include an extension electrode VDLa11 located in the idle area A. In this case, the resistance of the lower driving voltage line VDLa may be reduced. Accordingly, a voltage drop (IR drop) may also be reduced, thus minimizing the deviation of a driving current Isd. Therefore, the image quality of the display device can be improved.

As illustrated in FIG. 29, the extension electrode VDLa11 of the lower driving voltage line VDLa may overlap a first emission line EML1, a second emission line EML2, and a bias voltage line VBL.

According to a display device of one or more embodiments, flicker can be reduced or minimized even when the display device is driven at a low frequency.

In addition, according to the display device of one or more embodiments, leakage current and voltage drop can be reduced.

In addition, according to the display device of one or more embodiments, even when an image changes rapidly from a white gray level to a black gray level, an image corresponding to the black gray level can be accurately expressed.

In addition, according to the display device of one or more embodiments, a swing width of a data voltage can be reduced.

Therefore, according to the display device of one or more embodiments, the image quality and power consumption of the display device can be improved.

However, the aspects of the present disclosure are not restricted to the one set forth herein. The above and other aspects of the present disclosure will become more apparent to one of daily skill in the art to which the present disclosure pertains by referencing the claims.

The display device according to the embodiment can be applied to various electronic devices. The electronic device according to one embodiment includes the display device described above and may further include modules or devices having additional functions in addition to the display device.

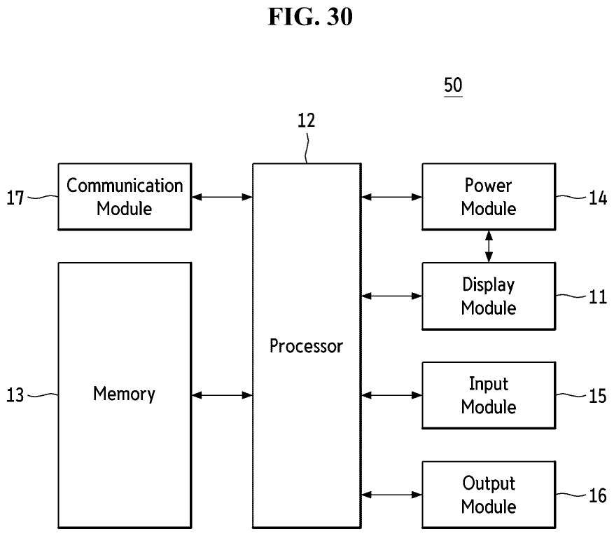

FIG. 30 is a block diagram of an electronic device according to one embodiment. Referring to FIG. 30, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

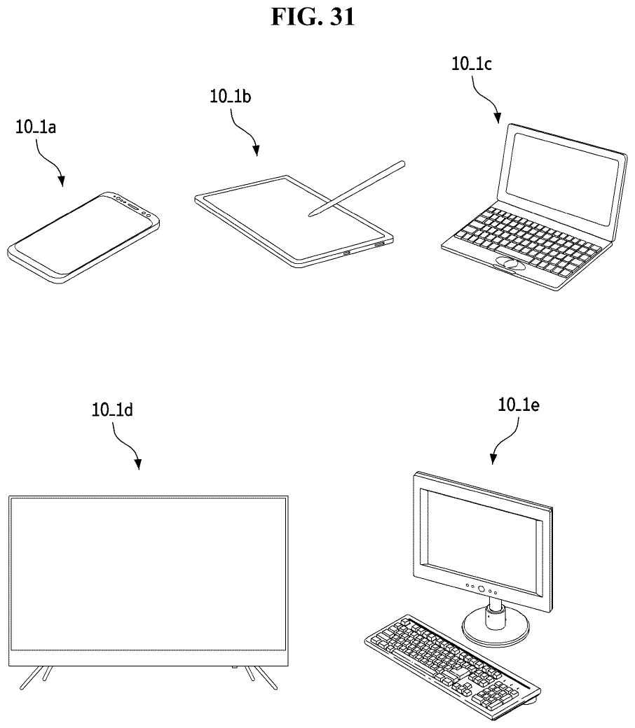

FIGS. 31, 32, and 33 are schematic diagrams of electronic devices according to various embodiments. FIGS. 31 to 33 illustrate examples of various electronic devices to which the display device according to the embodiments is applied.

FIG. 31 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

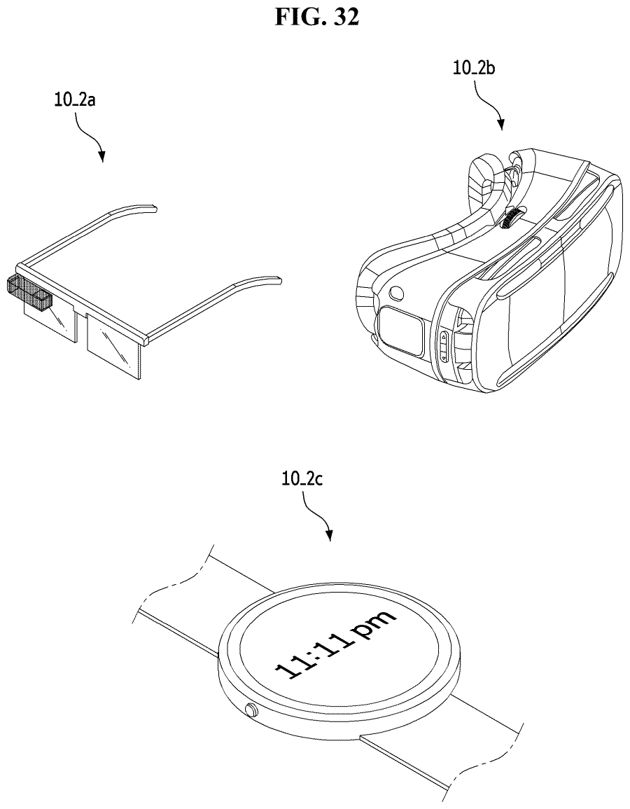

FIG. 32 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

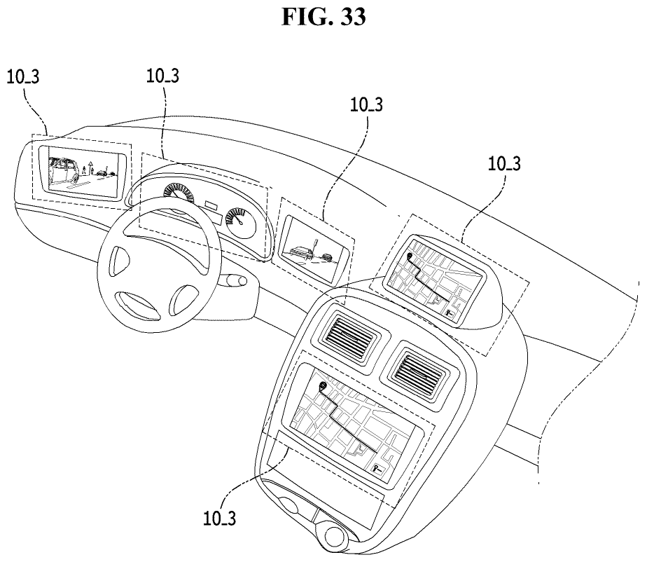

The smart watch 10_2c includes a biometric sensor as an input device, and may provide biometric information recognized by the biometric sensor to the user through the display module. FIG. 33 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the aspects of the present disclosure. Therefore, it is to be understood that the exemplary embodiments described above are illustrative rather than being restrictive in all aspects. It is to be understood that the scope of the present disclosure is defined by the claims, rather than the detailed description described above, and all modifications and alterations derived from the claims and their equivalents fall within the scope of the present disclosure.

What is claimed is:

1. A display device comprising:
a first transistor connected between a driving voltage line and a second node;
a sixth transistor connected between the second node and a common voltage line;
a light-emitting element connected between the sixth transistor and the common voltage line; and
a fourth transistor connected between the second node and an initialization voltage line.

2. The display device of claim 1, wherein an initialization voltage of the initialization voltage line is less than a driving voltage of the driving voltage line.

3. The display device of claim 1, further comprising:
a second transistor connected between a data line and a first node;
a third transistor connected between a third node and the second node;
a fifth transistor connected between the driving voltage line and the first node; and
a seventh transistor connected between a bias voltage line and the first node,
wherein the first transistor is connected between the first node and the second node, and
wherein a gate electrode of the first transistor is connected to the third node.

4. The display device of claim 3, further comprising:
a write gate line connected to a gate electrode of the second transistor;
a compensation gate line connected to a gate electrode of the third transistor;
an initialization gate line connected to a gate electrode of the fourth transistor;
a first emission line connected to a gate electrode of the fifth transistor;
a second emission line connected to a gate electrode of the sixth transistor;
a bias gate line connected to a gate electrode of the seventh transistor; and
a capacitor connected between the driving voltage line and the third node.

5. The display device of claim 4, wherein the write gate line is configured to transmit a write gate signal, the compensation gate line is configured to transmit a compensation gate signal, the initialization gate line is configured to transmit an initialization gate signal, the first emission line is configured to transmit a first emission signal, the second emission line is configured to transmit a second emission signal, the bias gate line is configured to transmit a bias gate signal, the driving voltage line is configured to transmit a driving voltage, the common voltage line is configured to transmit a common voltage, the initialization voltage line is configured to transmit an initialization voltage, and the bias voltage line is configured to transmit a bias voltage.

6. The display device of claim 5, wherein, in a first period, the second emission signal and the initialization gate signal have an active level, and the first emission signal, the compensation gate signal, the write gate signal, and the bias gate signal have a non-active level.

7. The display device of claim 6, wherein, in a second period after the first period, the compensation gate signal and the bias gate signal have an active level, and the first emission signal, the second emission signal, the initialization gate signal, and the write gate signal have a non-active level.

8. The display device of claim 7, wherein, in a third period after the second period, the initialization gate signal and the compensation gate signal have an active level, and the first emission signal, the second emission signal, the write gate signal, and the bias gate signal have a non-active level.

9. The display device of claim 8, wherein, in a fourth period after the third period, the compensation gate signal and the write gate signal have an active level, the first emission signal, the second emission signal, the initialization gate signal, and the bias gate signal have a non-active level, and a data voltage is provided to the data line.

10. The display device of claim 9, wherein, in a fifth period after the fourth period, the compensation gate signal has an active level, and the first emission signal, the second emission signal, the initialization gate signal, the write gate signal, and the bias gate signal have a non-active level.

11. The display device of claim 10, wherein, in a sixth period after the fifth period, the bias gate signal has an active level, and the first emission signal, the second emission signal, the initialization gate signal, the compensation gate signal, and the write gate signal have a non-active level.

12. The display device of claim 11, wherein, in a seventh period after the sixth period, the initialization gate signal has an active level, and the first emission signal, the second emission signal, the compensation gate signal, the write gate signal, and the bias gate signal have a non-active level.

13. The display device of claim 12, wherein in an eighth period after the seventh period, the first emission signal and the second emission signal have an active level, and the initialization gate signal, the compensation gate signal, the write gate signal, and the bias gate signal have a non-active level.

14. The display device of claim 3, wherein the fourth transistor comprises a transistor that is of a different type from the first transistor, the second transistor, the fifth transistor, the sixth transistor, and the seventh transistor.

15. The display device of claim 14, wherein the fourth transistor comprises an n-type transistor, and the first transistor, the second transistor, the fifth transistor, the sixth transistor, and the seventh transistor comprise p-type transistors.

16. The display device of claim 14, wherein the third transistor comprises a transistor of a same type as the fourth transistor.

17. The display device of claim 4, wherein the driving voltage line comprises:
a lower driving voltage line; and
an upper driving voltage line above the lower driving voltage line, and connected to the lower driving voltage line through a contact hole of an insulating layer.

18. The display device of claim 17, wherein the lower driving voltage line comprises an extension electrode.

19. The display device of claim 18, wherein the extension electrode overlaps the first emission line, the second emission line, and the bias voltage line.

20. An electronic device comprising a display device comprising:
a first transistor connected between a driving voltage line and a second node;
a sixth transistor connected between the second node and a common voltage line;
a light-emitting element connected between the sixth transistor and the common voltage line; and
a fourth transistor connected between the second node and an initialization voltage line.
